(19) United States
(12) Patent Application Publication
(10) Pub. No.: US 2011/0298038 A1
(43) Pub. Date: Dec. 8, 2011

(54) THREE DIMENSIONAL SEMICONDUCTOR DEVICE

(75) Inventors: Yong-Hoon SON, Yongin-si (KR); Kihyun Hwang, Seongnam-si (KR)

(73) Assignee: Samsung Electronics Co., Ltd.

(21) Appl. No.: 13/153,009

(22) Filed: Jun. 3, 2011

(30) Foreign Application Priority Data
Jun. 3, 2010 (KR) 10-2010-0052439

(51) Int. Cl. H01L 29/792

(52) U.S. Cl. 257/324; 257/E29.309

(57) ABSTRACT

Provided are a three-dimensional semiconductor memory device and manufacturing method of the three-dimensional semiconductor memory device. The three-dimensional semiconductor memory device may include a gate structure on a substrate with the gate structure including a plurality of gate electrodes. Conductive lines are disposed between the gate structure and the substrate. A horizontal semiconductor pattern is disposed between the gate structure and the conductive line. And a vertical semiconductor pattern penetrating the gate structure is connected to the horizontal semiconductor pattern.

### CROSS-REFERENCE TO RELATED APPLICATIONS

This U.S. non-provisional patent application claims priority under 35 U.S.C. §119 to Korean Patent Application No. 10-2010-0052439, filed on Jun. 3, 2010, the entire contents of which are hereby incorporated by reference.

### BACKGROUND OF THE INVENTIVE CONCEPT

Embodiments of the present inventive concept herein relate to semiconductor memory devices and methods of manufacturing the same, and, more particularly, to three-dimensional semiconductor memory devices having an improved electrical characteristic and methods of manufacturing the same.

To improve performance and reduce cost, the integration density of semiconductor memory devices may be increased. In a semiconductor memory device, a high integration may be desirable because integration is an important factor determining a price of a product. In a case of a conventional two dimensional semiconductor memory device, an integration of a semiconductor memory device may be affected by a level of a fine pattern formation technique because the integration is mainly determined by an area occupied by a unit memory cell. However, because expensive equipment may be required for forming a fine pattern, the integration density of two dimensional semiconductor memory devices may be increased but the level of increase may be limited.

To overcome the limitation, three-dimensional semiconductor memory devices including memory cells arranged in three dimensions are being introduced. However, for mass production of three-dimensional semiconductor memory devices, a process technology is desired that can realize a reliable product characteristic while realizing a manufacturing cost less than that of two dimensional semiconductor memory devices.

### SUMMARY

Embodiments of the inventive concept provide a three-dimensional semiconductor memory device. The three-dimensional semiconductor memory device may include a gate structure including a plurality of gate electrodes, the gate structure being disposed on a substrate; conductive lines between the gate structure and the substrate; a horizontal semiconductor pattern between the gate structure and the conductive lines; and a vertical semiconductor pattern penetrating the gate structure and connected to the horizontal semiconductor pattern.

Embodiments of the inventive concept also provide a manufacturing method of a three-dimensional semiconductor memory device including a conductive line between a substrate and a gate structure. The manufacturing method may include forming the conductive line by performing a replacement process. The replacement process includes forming a sacrificial layer between the substrate and the gate structure; forming a recess region by removing a portion of the sacrificial layer; and filling the recess region with a conductive material.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the figures:

FIG. 1 is a circuit diagram of a three-dimensional semiconductor memory device in accordance with exemplary embodiments of the inventive concept.

FIG. 2 is a perspective view of a three-dimensional semiconductor memory device in accordance with an embodiment of the inventive concept.

FIG. 3 is a cross-sectional view of the three-dimensional semiconductor memory device illustrated in FIG. 2.

FIGS. 4 through 8 are cross-sectional views of the three-dimensional semiconductor memory devices in accordance with some modified embodiments of the inventive concept.

FIGS. 9 through 12 are views illustrating a portion (‘A’ part of FIG. 2) of three-dimensional semiconductor memory device in accordance with some other embodiments of the inventive concept.

FIG. 13 is a perspective view of a three-dimensional semiconductor memory device in accordance with another embodiment of the inventive concept.

FIG. 14 is a cross-sectional view of the three-dimensional semiconductor memory device illustrated in FIG. 13.

FIG. 15 is a perspective view of a three-dimensional semiconductor memory device in accordance with still another embodiment of the inventive concept.

FIG. 16 is a circuit diagram for describing the three-dimensional semiconductor memory device illustrated in FIG. 15.

FIGS. 17A through 26A are perspective views illustrating a method of manufacturing a three-dimensional semiconductor memory device in accordance with an embodiment of the inventive concept.

FIGS. 17B through 26B are cross-sectional views illustrating a method of manufacturing a three-dimensional semiconductor memory device in accordance with an embodiment of the inventive concept.

FIGS. 27 through 33 are cross-sectional views illustrating a method of manufacturing a three-dimensional semiconductor memory device in accordance with the embodiment illustrated in FIGS. 13 and 14.

FIG. 34 is a block diagram illustrating an example of a memory system including a three-dimensional semiconductor memory device in accordance with exemplary embodiments of the inventive concept.

FIG. 35 is a block diagram illustrating an example of a memory card including a three-dimensional semiconductor memory device in accordance with exemplary embodiments of the inventive concept.

FIG. 36 is a block diagram illustrating an example of an information processing system including a three-dimensional semiconductor memory device in accordance with exemplary embodiments of the inventive concept.

### DETAILED DESCRIPTION OF THE EMBODIMENTS

Embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout the specification.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Embodiments of the inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Hereinafter, referring to drawings, exemplary embodiments of the inventive concept will be described in detail.

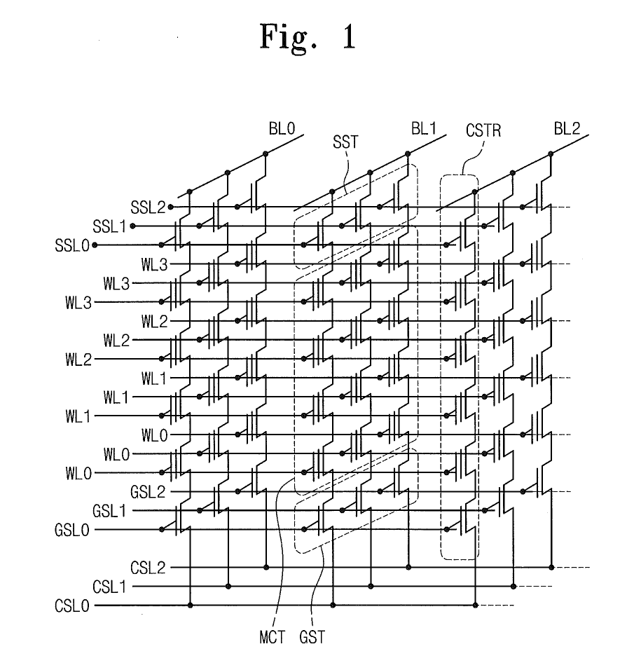

FIG. 1 is a circuit diagram of a three-dimensional semiconductor memory device in accordance with exemplary embodiments of the inventive concept.

Referring to FIG. 1, a three-dimensional semiconductor memory device in accordance with an embodiment of the inventive concept may include common source lines CSL0-CSL2, a plurality of bit lines BL0-BL2, and a plurality of cell strings CSTR disposed between one of the common source lines CSL0-CSL2 and the bit lines BL0-BL2.

The bit lines BL0-BL2 are two dimensionally arranged and the plurality of cell strings CSTR is connected to each of the bit lines BL0-BL2 in parallel. The cell strings CSTR may be connected to the common source lines CSL0-CSL2 in common. That is, the plurality of cell strings CSTR may be disposed between the common source lines CSL0-CSL2 and the bit lines BL0-BL2. According to an embodiment, the common source lines CSL0-CSL2 may be a plurality of lines arranged in two dimensions. Here, a same voltage may be applied to the common source lines CSL0-CSL2 or each of the common source lines CSL0-CSL2 may be electrically controlled.

Each of the cell strings CSTR may be comprised of a ground select transistor GST connected to the common source lines CSL0-CSL2, a string select transistor SST connected to the bit lines BL0-BL2, and a plurality of memory cell transistors MCT disposed between the ground and string select transistors GST, SST. The ground select transistor GST, the string select transistor SST, and the memory cell transistor MCT may be serially connected.

The common source lines CSL0-CSL2 may be connected to sources of the ground select transistor GST in common. In addition, ground select lines GSL0-GSL2, word lines WL0-WL3, and string select lines (SSL0-SSL2) that are disposed between the common source lines CSL0-CSL2 and the bit lines BL0-BL2 may be used as gate electrodes of the ground select transistor GST, the memory cell transistor MCT, and the string select transistor SST, respectively. Also, each of the memory cell transistors MCT includes an information storage substance.

Because one cell string CSTR is comprised of a plurality of memory cell transistors MCT spaced different distances apart from the common source lines CSL0-CSL2, multi-layer word lines are disposed between the common source lines CSL0-CSL2 and the bit lines BL0-BL2.

Gates electrodes of memory cell transistors MCT spaced a same distance apart from the common source lines CSL0-CSL2 are connected to one of the word lines WL0-WL3 in common and thereby the gates may have an equivalent electrical potential. Alternatively, even though gate electrodes of memory cell transistors MCT are spaced a same distance apart from the common source lines CSL0-CSL2, gate electrodes disposed on different rows and columns may be independently controlled.

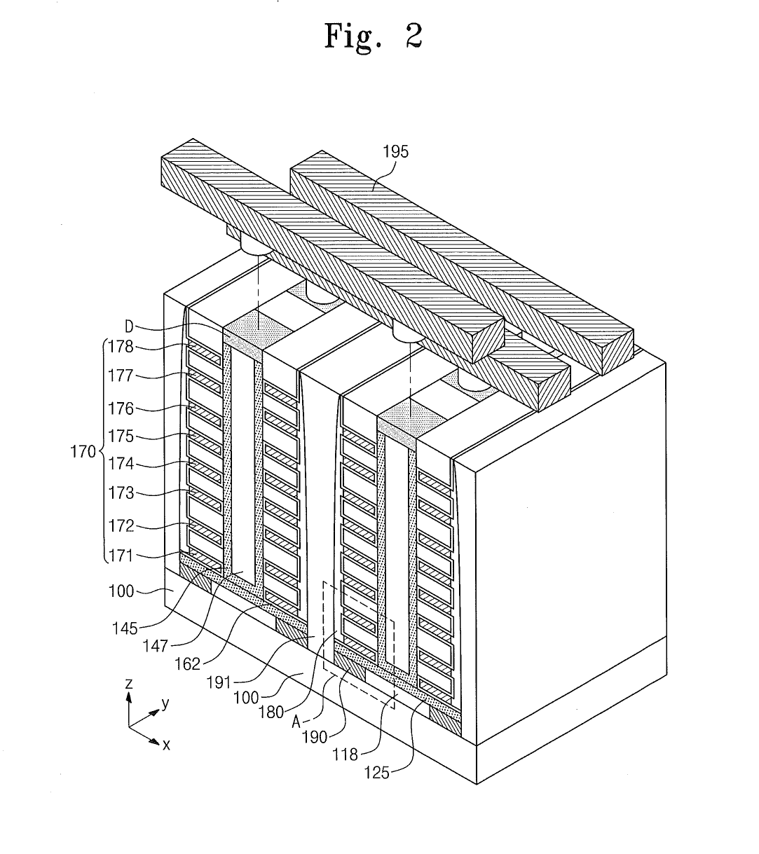

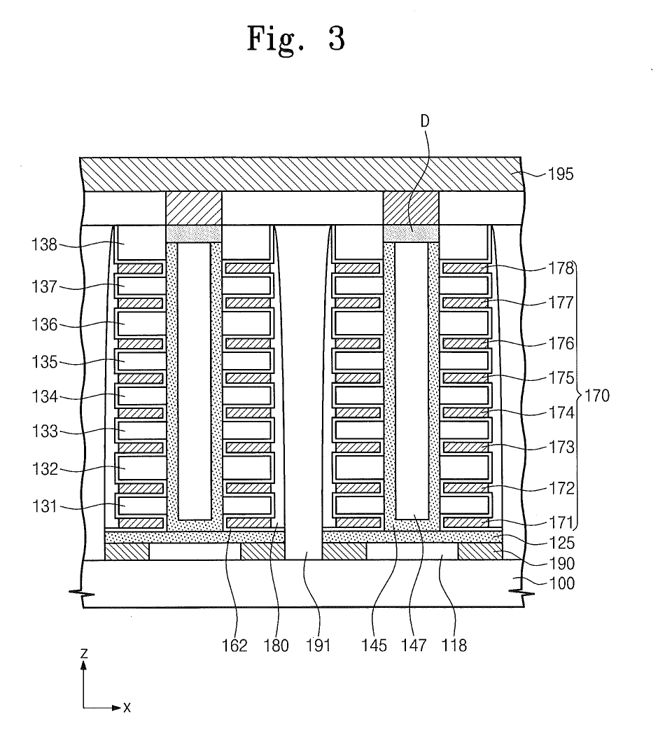

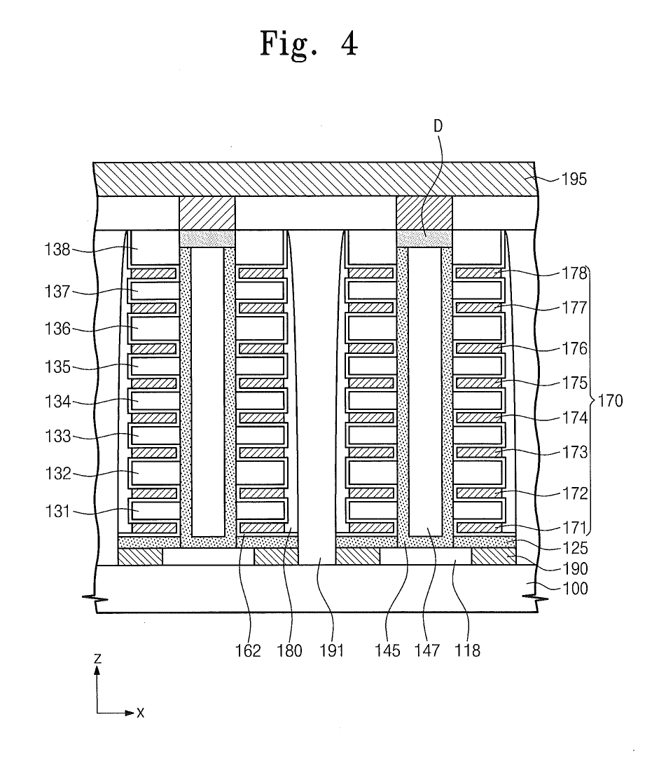

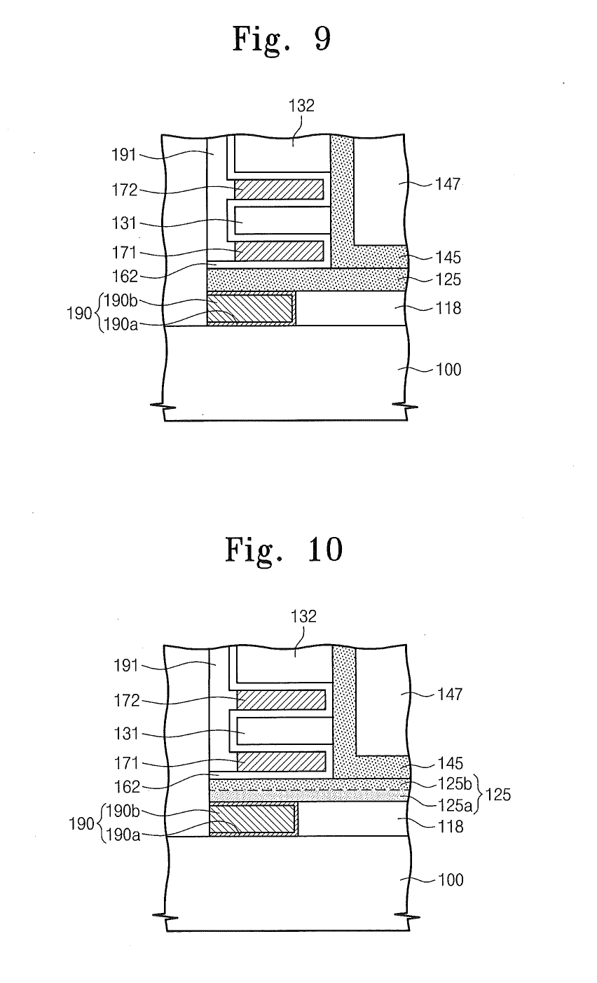

FIG. 2 is a perspective view of a three-dimensional semiconductor memory device in accordance with an embodiment of the inventive concept. FIG. 3 is a cross-sectional view of the three-dimensional semiconductor memory device illustrated in FIG. 2. FIGS. 4 through 8 are cross-sectional views of three-dimensional semiconductor memory devices in accordance with some embodiments of the inventive concept. FIGS. 9 through 12 are views illustrating a portion (‘A’ part of FIG. 2) of three-dimensional semiconductor memory device in accordance with some other modified embodiments of the inventive concept.

Referring to FIGS. 1 and 2, a three-dimensional semiconductor memory device may include a gate structure 170 including a plurality of gate electrodes 171-178 stacked on a substrate 100, a horizontal semiconductor pattern 125 disposed between the substrate 100 and the gate structure 170, common source conductive lines 190 disposed between the substrate 100 and the horizontal semiconductor pattern 125, vertical semiconductor patterns 145 connected to the horizontal semiconductor pattern 125 while crossing one sidewall of the gate electrodes 171-178 and bit lines 195 connected to the vertical semiconductor patterns 145 while crossing the gate electrodes 171-178 on the gate structure 170.

The substrate 100 may be selected from a material having a semiconductor characteristic (e.g., a silicon wafer, a silicon layer, a germanium layer and a silicon-germanium layer), an insulating material (e.g., an insulating layer and a glass), and a semiconductor covered with an insulating material (e.g., a silicon-on-insulator (SOI) substrate).

According to an embodiment, gate electrodes 171-172 and 177-178 continuously stacked in a lower portion and an upper portion of the gate structure 170 may be used as the ground and string select lines (GSL0-GSL2 and SSL0-SSL2) illustrated in FIG. 1, respectively. According to another embodiment, in the gate structure 170, gate electrodes of top and bottom layers 178 and 171 may be used as the string and ground select lines (SSL0-SSL2, GSL0-GSL2) illustrated in FIG. 1 and the rest gate electrodes 173-176 may be used as the word lines WL0-WL3 illustrated in FIG. 1. The gate electrodes 178 and 171 used as the string and ground select lines (SSL0-SSL2, GSL0-GSL2) may be thicker than the gate electrodes 173-176 used as the word lines WL0-WL3.

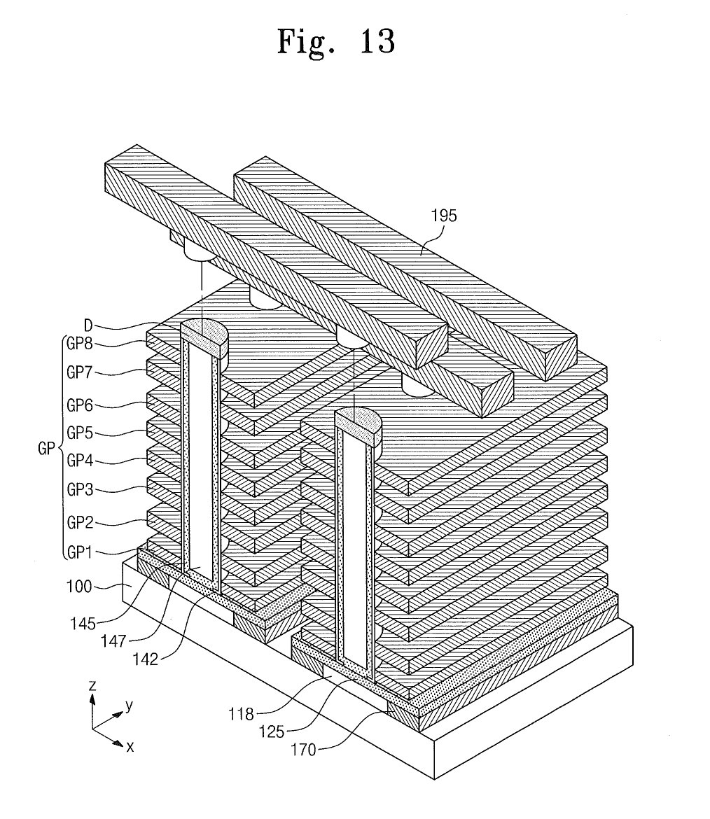

The gate electrodes 171-178 may be formed to have a line shape extending in a specific direction and may be arranged on the substrate 100 in three dimensions. According to a shape of the gate electrodes 171-178, the gate structure 170 may also have a line shape extending in a specific direction. In the gate structure 170, the gate electrodes 171-178 disposed on different layers can be electrically separated from one another. In the gate structure 170, the gate electrodes 171-178 disposed on the same layer can be electrically connected in common or can be electrically separated from one another. Also, insulating layers 131-138 may be interposed between vertically adjacent gate electrodes 171-178 and a plurality of vertical semiconductor patterns 145 may be disposed on sidewalls of the gate electrodes 171-178 having a line shape. According to an embodiment, the gate electrodes 171-178 having a line shape may be disposed on both sidewalls of the vertical semiconductor pattern 145 as illustrated in FIG. 2. A plurality of vertical semiconductor patterns 145 may penetrate the gate electrodes 171-178 having a line shape as illustrated in FIG. 13.

The gate electrodes 171-178 may be comprised of a conductive material. For example, the gate electrodes 171-178 may include at least one material selected from doped semiconductor (e.g., doped silicon, doped germanium, doped silicon-germanium, etc.), metal (e.g., tungsten, titanium, tantalum, tantalum aluminum, etc.), metal nitrides (e.g., titanium nitride, tantalum nitride, etc.), and metal silicides (e.g., tungsten silicide, cobalt silicide, titanium silicide, nickel silicide, etc.).

Also, a spacer 180 may be formed on an outer sidewall of the gate structure 170 spaced apart from the vertical semiconductor pattern 145 and may be formed from an insulating material. For example, the spacer 180 may include at least one material selected from oxide, nitride, carbide and oxynitride.

A plurality of gate structures 170 may be disposed on the substrate 100. A horizontal semiconductor pattern 125 may be disposed below a pair of gate structures 170. A gate separation insulating pattern 191 spaced apart from the vertical semiconductor pattern 145 may be disposed between the adjacent gate structures 170. The gate separation insulating pattern 191 may include at least one material selected from a nitride, a carbide, and an oxynitride and may be formed from the same material as the spacer 180. Also, the gate separation insulating pattern 191 may extend between the adjacent horizontal semiconductor patterns 125 to directly contact the substrate 100. Alternatively, the gate separation insulating pattern 191 may extend between the adjacent horizontal semiconductor patterns 125 to contact a top surface of the common source conductive line 190.

The horizontal semiconductor pattern 125 may be disposed below the gate structure 170 or a pair of gate structures 170 and may be spaced apart from a top surface of the substrate 100. According to an embodiment, the horizontal semiconductor pattern 125 may be a conductive pattern having a line shape parallel to the gate electrodes 171-178. According to another embodiment, as illustrated in FIG. 4, a plurality of vertical semiconductor patterns 145 may penetrate the horizontal semiconductor pattern 125 having a line shape. In this case, a plurality of penetration regions may be defined in the horizontal semiconductor pattern 125.

According to an embodiment, as illustrated in FIG. 2, a pair of gate structures 170 sharing the vertical semiconductor pattern 145 may be disposed on the horizontal semiconductor pattern 125. According to another embodiment, as illustrated in FIG. 3, one gate structure 170 having a line shape, which a plurality of vertical semiconductor patterns 145 penetrates, may be disposed on the horizontal semiconductor pattern 125.

The horizontal semiconductor pattern 125 may include silicon (Si), germanium (Ge) or a compound thereof. The horizontal semiconductor pattern 125 may include at least one of a single crystalline semiconductor, an amorphous semiconductor, and a polycrystalline semiconductor. Also, the horizontal semiconductor pattern 125 may be a single crystalline semiconductor formed by performing a phase change of amorphous silicon or polysilicon through a thermal process. The horizontal semiconductor pattern 125 may be a single crystalline semiconductor formed through an epitaxial growth process using the substrate 100 as a seed.

The horizontal semiconductor pattern 125 may be a semiconductor doped with an impurity or may be an intrinsic semiconductor of an undoped state. In the case that the horizontal semiconductor pattern 125 is formed of semiconductor material doped with an impurity, an entire portion of the horizontal semiconductor pattern 125 or an upper portion of the horizontal semiconductor pattern 125, which is in contact with the vertical semiconductor pattern 145, may have the same conductivity type as the vertical semiconductor pattern 145.

A thickness of the horizontal semiconductor pattern 125, as will be described with reference to FIG. 9, may be equal to or less than a thickness of an inversion layer formed in the horizontal semiconductor pattern 125. Also, a thickness of the horizontal semiconductor pattern 125 may be greater than a thickness of the inversion layer.

The vertical semiconductor pattern 145 may be two dimensionally arranged on the horizontal semiconductor pattern 125 and may be perpendicular to the horizontal semiconductor pattern 125. The vertical semiconductor pattern 145 may have a vertical pillar shape, a hollow cylindrical shape, a cup shape, or a U character shape and a buried insulating pattern may fill the inside of the vertical semiconductor pattern 145 having a hollow cylindrical shape. A thickness of the vertical semiconductor pattern 145 may be equal to or less than a thickness of the horizontal semiconductor pattern 125. The vertical semiconductor pattern 145 may further include an impurity region D having a different conductivity type from the vertical semiconductor pattern 145 in a region where the vertical semiconductor pattern 145 is connected to the bit line.

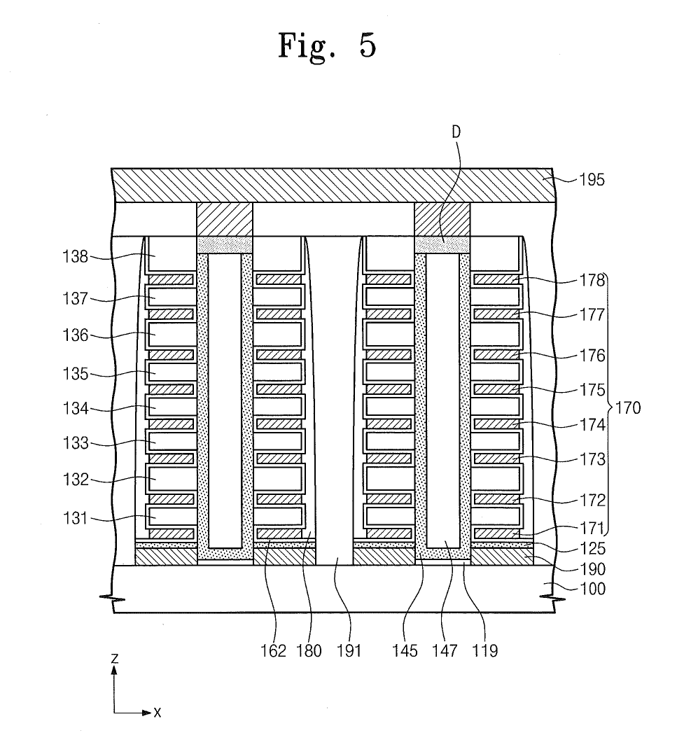

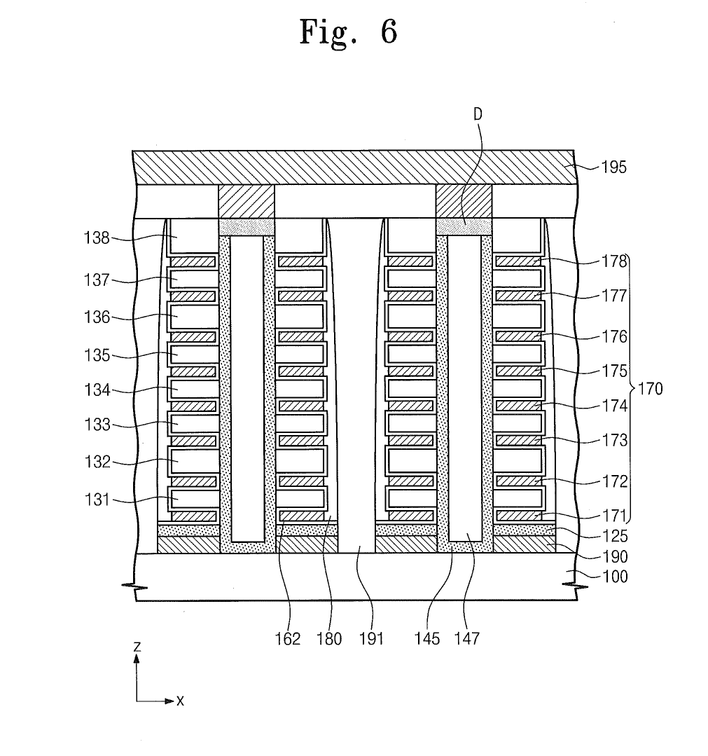

Also, the vertical semiconductor pattern 145 may be directly in contact with the horizontal semiconductor pattern 125 or may have a structure such that the vertical semiconductor pattern 145 is inserted into the horizontal semiconductor pattern 125. More specifically, the vertical semiconductor pattern 145, as illustrated in FIG. 4, may penetrate the horizontal semiconductor pattern 125 to be formed on a support pattern 118. That is, the vertical semiconductor pattern 145 may directly contact a sidewall of the horizontal semiconductor pattern 125. According to another embodiment, as illustrated in FIG. 5, the vertical semiconductor pattern 145 may directly contact a portion of the sidewall of the common source conductive line 190. As illustrated in FIG. 6, the vertical semiconductor pattern 145 may penetrate the horizontal semiconductor pattern 125 to directly contact the substrate 100. In this case, both sidewalls of the vertical semiconductor pattern 145 may directly contact the common source conductive line 190. In the case that the vertical semiconductor pattern 145 directly contacts the common source conductive line 190, the horizontal semiconductor pattern 125 may be formed from an insulating material and a thickness of the horizontal semiconductor pattern 125 may be equal to or less than thicknesses of the insulating layers 131-138 between the gate electrodes 171-178. As illustrated in FIGS. 5 and 6, in the case that the common source conductive line 190 directly contacts the horizontal semiconductor pattern 125, a schottky-barrier junction may be formed between the common source conductive line 190 and the horizontal semiconductor pattern 125.

The vertical semiconductor pattern 145 may include silicon (Si), germanium (Ge) or a compound thereof. The vertical semiconductor pattern 145 may include at least one of a single crystalline semiconductor, an amorphous semiconductor, and a polycrystalline semiconductor. Also, the vertical semiconductor pattern 145 may be a single crystalline semiconductor formed by performing a phase change of amorphous silicon or polysilicon through a thermal process. The vertical semiconductor pattern 145 may be a semiconductor formed through an epitaxial growth process using the horizontal semiconductor pattern 125 as a seed. The vertical semiconductor pattern 145 may be a semiconductor doped with an impurity or may be an intrinsic semiconductor of an undoped state.

Also, the vertical semiconductor pattern 145 may have a discontinuous interface at an interface between the vertical semiconductor pattern 145 and the horizontal semiconductor pattern 125. The vertical semiconductor pattern 145 may vertically extend from the horizontal semiconductor pattern 125 without a discontinuous interface.

The common source conductive line 190 may be a conductive pattern disposed between the horizontal semiconductor pattern 125 and the substrate 100. The common source conductive line 190 directly contacts a portion of bottom surface of the horizontal semiconductor pattern 125. The common source conductive line 190 may include at least one material selected from metal (e.g., tungsten, titanium, tantalum, tantalum aluminum, etc.), conductive metal nitrides (e.g., titanium nitride, tantalum nitride, etc.), and metal silicides (e.g., tungsten silicide, cobalt silicide, titanium silicide, nickel silicide, etc.). For example, as illustrated in FIGS. 9 through 12, the common source conductive line 190 may be formed from a metal line (e.g., tungsten 190b) having a low resistivity, and a barrier metal layer (e.g., conductive metal nitride 190a) or a silicide layer (not illustrated) may be further formed between the horizontal semiconductor pattern 125 and the metal line 190b. Because the common source conductive line 190 is formed from metal material having a low resistivity, an operation speed of a three-dimensional semiconductor memory device can be improved.

According to an embodiment, the common source conductive line 190, as illustrated in FIG. 3, may be disposed to be spaced apart from the vertical semiconductor pattern 145 below both sides of the vertical semiconductor pattern 145. A support pattern 118 composed of insulating material may be formed between the common source conductive lines 190. The support pattern 118 is formed of an insulating material having an etching selectivity with respect to the insulating layers 131-138 of the gate structure 170. The support pattern 118 may include at least one material selected from oxide, nitride, carbide, and oxynitride. Horizontal widths of the common source conductive line 190 and the support pattern 118, as will be described below, may vary with a replacement process for forming the common source conductive line 190. Also, a thickness of the support pattern 118 may be equal to a thickness of the common source conductive line 190. According to another embodiment, a thickness of the support pattern 118 may be less than a thickness of the common source conductive line 190. According to still another embodiment, as illustrated in FIG. 6, in the case that the vertical semiconductor pattern 145 is in contact with the substrate 100, the support pattern 118 may be omitted.

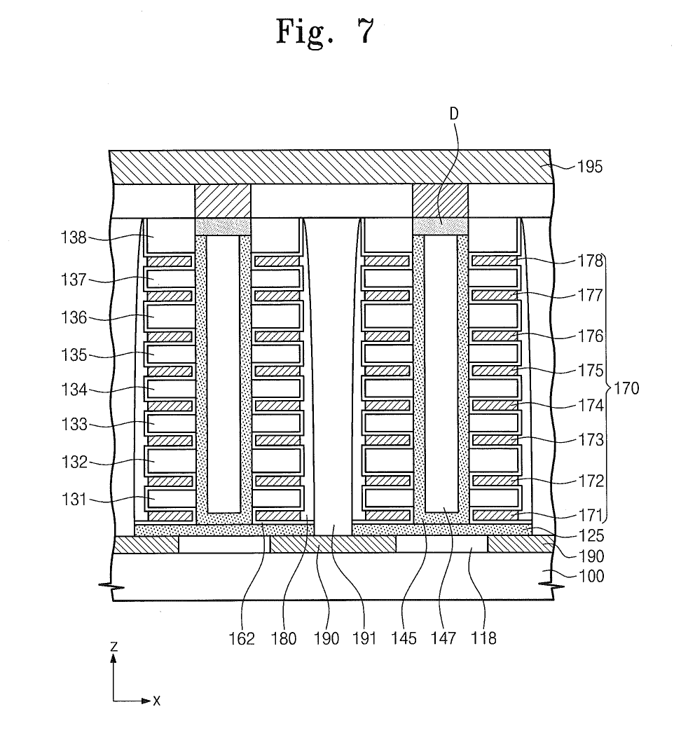

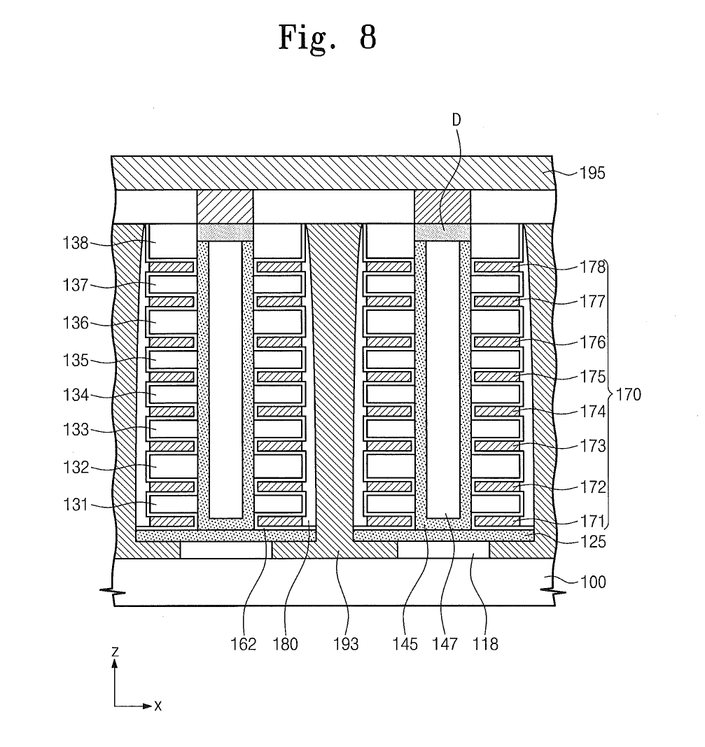

Also, according to an embodiment illustrated in FIG. 7, the common source conductive line 190 may be disposed below adjacent gate structures 170 in common. That is, the common source conductive line 190 may be disposed between adjacent horizontal semiconductor patterns 125. In this case, the gate separation insulating pattern 191 may be formed between the gate structures 170 on the common source conductive line 125. According to an embodiment illustrated in FIG. 8, the common source conductive line 190 may extend from below the gate structure 170 to between the gate structures 170. In this case, a top surface of the common source conductive line 190 rises and thereby a process to form an interconnection electrically connected to the common source conductive line 190 is readily performed. The common source conductive line 190 can function as a shield, thereby reducing a capacitive coupling between horizontally adjacent conductive patterns 230. Thus, a disturbance in program and read operations of a three-dimensional semiconductor memory device may be reduced.

According to embodiments illustrated in FIGS. 2 through 8, a data storage layer 162 may be disposed between the vertical semiconductor pattern 145 and the gate electrodes 171-178. According to an embodiment, the data storage layer 162 may be a charge storage layer. For example, the charge storage layer may be one of a charge trap insulating layer, a floating gate electrode, and an insulating layer including conductive nano dots. In the case that the data storage layer 162 is a charge storage layer, data stored in the data storage layer 162 may be varied using Fowler-Nordheim tunneling caused by a voltage difference between the vertical semiconductor pattern 145 and gate conductive patterns. The data storage layer 162 contacting a gate electrode used as string and ground select lines may be used as a gate insulating layer. At least one gate insulating layer of string and ground select transistors (SST, GST) may be formed from the same material as the data storage layer of the memory cell transistor MCT but may be a gate insulating layer (e.g., a silicon oxide layer) for a conventional MOSFET. The data storage layer 162 may be a thin layer (e.g., a thin layer for a phase change memory or a thin layer for a variable memory) that can store data on the basis of a different operation principle.

According to an embodiment, the data storage layer 162 may be a charge trap insulating layer having traps for storing charges. The data storage layer 162, as illustrated in FIGS. 9 and 10, may extend from between the vertical semiconductor pattern 145 and the gate electrodes 171 and 172 to top and bottom surfaces of the gate electrodes 171 and 172. The data storage layer 162 may cover sidewalls of the insulating layers 131 and 132 spaced apart from the vertical semiconductor pattern 145. The data storage layer 162 may also be disposed between a bottom surface of the lowermost layer gate electrode 171 and the horizontal semiconductor pattern 125 to be used as a gate insulating layer of the ground select transistor GST.

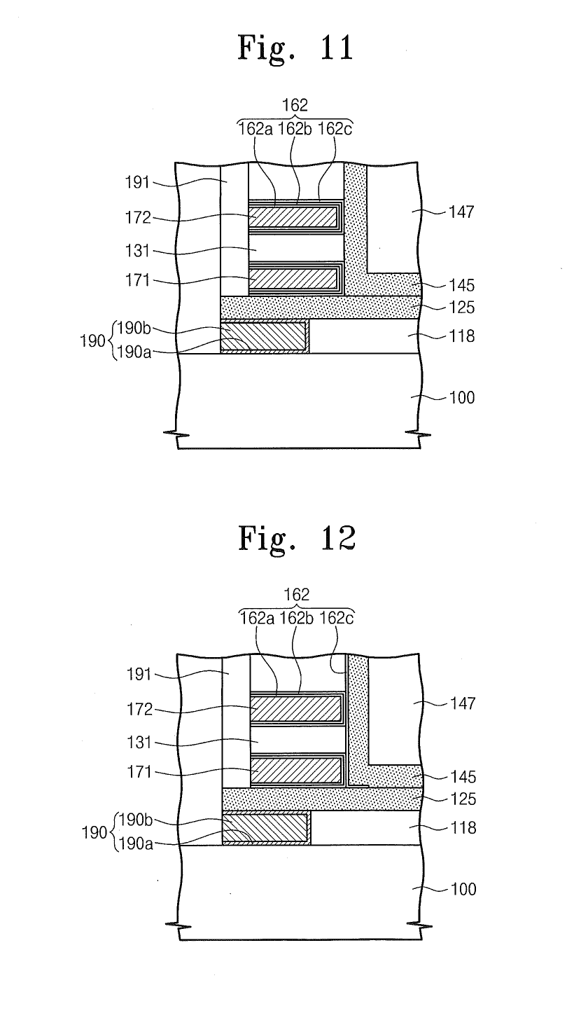

According to another embodiment, as illustrated in FIG. 11, the data storage layer 162 may be locally formed between the vertically adjacent insulating layers 131 and 132 and may be separated from vertically adjacent other data storage layers 162. In the case that the data storage layers 162 are vertically separated from one another, charges trapped in the data storage layer 162 may be prevented from spreading to an adjacent other charge trap insulating layer. Even in the case that the data storage layer 162 is locally formed between the vertically adjacent insulating layers 131 and 132, the lowermost layer of the data storage layer 162 may be disposed between a bottom surface of the lowermost layer gate electrode 171 and the horizontal semiconductor pattern 125.

The data storage layer 162, as illustrated in FIG. 11, may include a blocking insulating layer 162a, a charge trap layer 162b, and a tunnel insulating layer 162c that are sequentially stacked. Here, the blocking insulating layer 162a may be in contact with the gate electrodes 171 and 172 and the tunnel insulating layer 162c may be in contact with the vertical semiconductor pattern 145. The tunnel insulating layer 162c may include at least one material selected from oxide, nitride, and oxynitride. The blocking insulating layer 162a may include at least one material selected from an oxide and a dielectric substance having a high dielectric constant (e.g., a hafnium oxide, an aluminum oxide, etc.). The charge trap layer 162b may include at least one material selected from a nitride, an oxide, a dielectric substance including nano dots, and a metal nitride.

Also, in the data storage layer 162 including the blocking insulating layer 162a, the charge trap layer 162b, and the tunnel insulating layer 162c that are sequentially stacked, the tunnel insulating layer 162c, as illustrated in FIG. 12, may extend from one side of the gate electrodes 171 and 172 to between the vertical semiconductor pattern 145 and the insulating layers 131 and 132. The blocking insulating layer 162a and the charge trap layer 162b may extend into top and bottom surfaces of the gate electrodes 171 and 172. Although not illustrated in the drawing, the tunnel insulating layer 162c and the charge trap layer 162b extend between the vertical semiconductor pattern 145 and the insulating layers 131 and 132 at one side of the gate electrodes 171 and 172. The blocking insulating layer 162a may extend into top and bottom surfaces of the gate electrodes 171 and 172.

In the three-dimensional semiconductor memory device in accordance with the embodiments of the inventive concept, the ground select transistor GST, the memory cell transistors MCT, and the string select transistor SST described with reference to FIG. 1 may be formed. One memory cell transistor MCT may include a gate electrode 173, 174, 175 or 176, a portion of the vertical semiconductor pattern 145 adjacent to the gate electrode 173, 174, 175 or 176 and the data storage layer 162 between the portion of the vertical semiconductor pattern 145 and the gate electrode 173, 174, 175 or 176. At least a portion of the vertical semiconductor pattern 145 adjacent to the gate electrodes 171-178 is used as channel regions of the string and ground select transistors (SST, GST) and the memory cell transistor MCT.

When a three-dimensional semiconductor memory device operates, an inversion layer may be generated in the vertical semiconductor pattern 145 adjacent to the gate electrodes 171-178. The inversion layer may extend into a portion adjacent to the insulating layers 131-138 between the gate electrodes 171-178 by a fringing field provided from the gate electrodes 171-178 to which a predetermined voltage is applied. The inversion layer adjacent to the insulating layers 131-138 may be used as source/drain regions of transistors. In this case, the string and ground select transistors (SST, GST) and the memory cell transistor MCT may be electrically connected by sharing the inversion layers formed by a fringing field provided from the gate electrodes 171-178 to which a predetermined voltage is applied. A thickness of the insulating layers 131-138 between the gate electrodes 171-178 may be controlled so that the inversion layer can be shared by the fringing field. A horizontal thickness of the inversion layer generated in the vertical semiconductor pattern 145 may be equal to or less than a thickness of the vertical semiconductor pattern 145. In the case that a horizontal thickness of the inversion layer is equal to a thickness of the vertical semiconductor pattern 145, the vertical semiconductor pattern 145 may be completely depleted.

The inversion layer generated when a predetermined voltage is applied to the lowermost layer gate electrode 171 may be generated not only in the vertical semiconductor pattern 145 adjacent to the lowermost layer gate electrode 171 but also in the horizontal semiconductor pattern 125. That is, the inversion layer may include a vertical region formed in the vertical semiconductor pattern 145 and a horizontal region formed in the horizontal semiconductor pattern 125. The vertical and horizontal regions of the inversion layer may be conformally connected to each other. Here, the horizontal region of the inversion layer may be used as a source region of the ground select transistor GST and the vertical region of the inversion layer may be used as a channel region of the ground select transistor GST.

According to an embodiment, a horizontal thickness of the horizontal region of the inversion layer formed in the horizontal semiconductor pattern 125 may be equal to a thickness of the horizontal semiconductor pattern 125. In this case, in the horizontal semiconductor pattern 125, a portion of position between the common source conductive line 190 and the lowermost layer gate electrode 171 may be completely depleted. That is, when a three-dimensional semiconductor memory device operates, the ground select transistor GST and the common source conductive line 190 (i.e., CSL of FIG. 1) may be electrically connected to each other by the inversion layer formed in the horizontal semiconductor pattern 125. Thus, when a three-dimensional semiconductor memory device operates, charges can move from the common source line (CSL of FIG. 1) to the bit line (BL0, BL1 or BL2) through the inversion layer formed in the vertical and horizontal semiconductor patterns 145 and 125.

According to another embodiment, as illustrated in FIG. 10, a thickness of the horizontal semiconductor pattern 125 may be greater than a thickness of the inversion layer generated in the horizontal semiconductor pattern 125 by the lowermost layer gate electrode 171. In this case, to electrically connect the ground select transistor GST and the common source line (CSL), an impurity having a different conductivity type from the vertical semiconductor pattern 145 may be implanted into a lower portion of the horizontal semiconductor pattern 125 adjacent to the common source conductive line 190. That is, a first impurity region 125a may be formed at a lower portion of the horizontal semiconductor pattern 125 and a second impurity region 125b having the same conductivity type as the vertical semiconductor pattern 145 may be formed at an upper portion of the horizontal semiconductor pattern 125. In this case, an inversion layer may be generated in an upper portion of the horizontal semiconductor pattern 125 by the lowermost layer gate electrode 171 to which a predetermined voltage is applied. The inversion layer may be electrically connected to the first impurity region 125a.

According to the embodiment illustrated in FIGS. 5 and 6, the vertical semiconductor pattern 145 penetrates the horizontal semiconductor pattern 125 to directly contact the common source conductive line 190. In this case, when a three-dimensional semiconductor memory device operates, the inversion layer formed in the vertical semiconductor pattern 145 by the lowermost layer gate electrode 171 to which a predetermined voltage is applied can extend into a portion adjacent to a sidewall of the common source conductive line 190. Thus, the inversion layer formed in the horizontal semiconductor pattern 125 and the inversion layer formed at a lower portion of the vertical semiconductor pattern 145 may be used as a source region of the ground select transistor GST. In the case that the vertical semiconductor pattern 145 directly contacts the common source conductive line 190, an insulating layer instead of the horizontal semiconductor pattern 125 may be disposed between the common source conductive line 190 and the lowermost layer gate electrode.

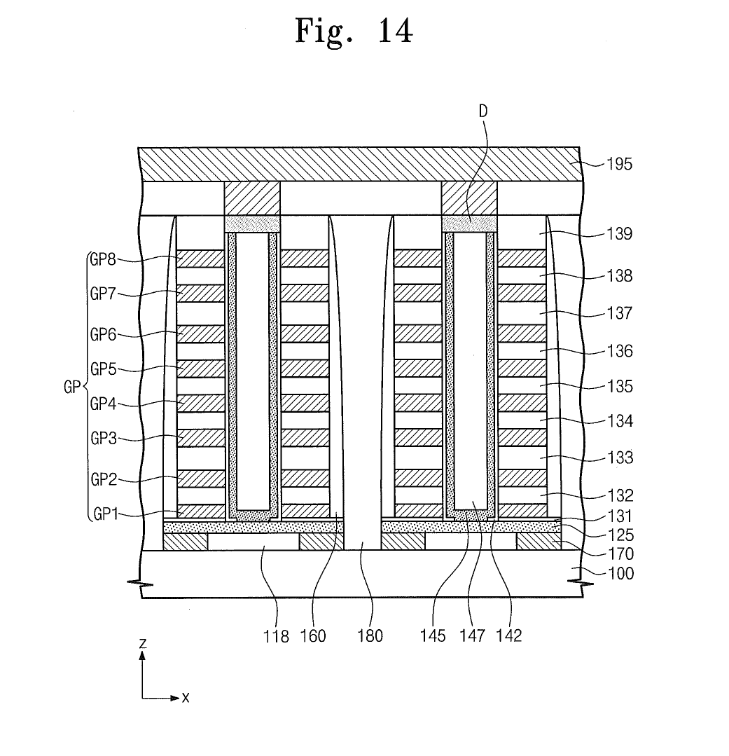

FIG. 13 is a perspective view of a three-dimensional semiconductor memory device in accordance with another embodiment of the inventive concept. FIG. 14 is a cross-sectional view of the three-dimensional semiconductor memory device illustrated in FIG. 13.

Referring to FIGS. 13 and 14, similar to that described in the embodiments described above, a three-dimensional semiconductor memory device in accordance with another embodiment of the inventive concept may include a gate structure 170 such that gate electrodes 171-178 are stacked on a substrate 100, a horizontal semiconductor pattern 125 between the gate structure 170 and the substrate 100, a common source conductive lines 190 between the horizontal semiconductor pattern 125 and the substrate 100, vertical semiconductor patterns 145, which are in contact with the horizontal semiconductor pattern 125 while crossing sidewalls of the gate electrodes 171-178, and bit lines 195, which are in contact with the vertical semiconductor patterns 145 while crossing the gate electrodes 171-178. According to another embodiment, the three-dimensional semiconductor memory device may have the same structure as the embodiment described above except for differences described below.

According to another embodiment, the gate structure 170 has a line shape and a plurality of vertical semiconductor patterns 145 penetrates one gate structure 170. Also, the vertical semiconductor pattern 145 can penetrate the horizontal semiconductor pattern 125 and in this case, the horizontal semiconductor pattern 125 and the gate electrodes 171-178 on the horizontal semiconductor pattern 125 may have the same shape.

Also, according to another embodiment, a data storage layer 142 can cross a plurality of gate electrodes 171-178 and one sidewall of the insulating layers 131-138 and may be formed around the vertical semiconductor pattern 145. A buffer dielectric layer 131 may be disposed between the lowermost gate electrode 171 and the horizontal semiconductor pattern 125. The buffer dielectric layer 131 may be a silicon oxide layer formed through a thermal oxidation process.

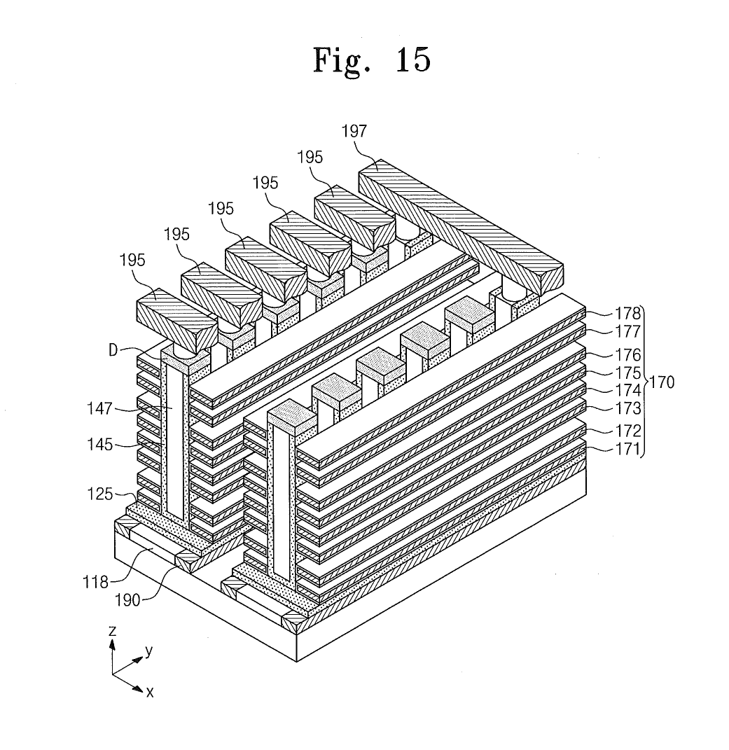

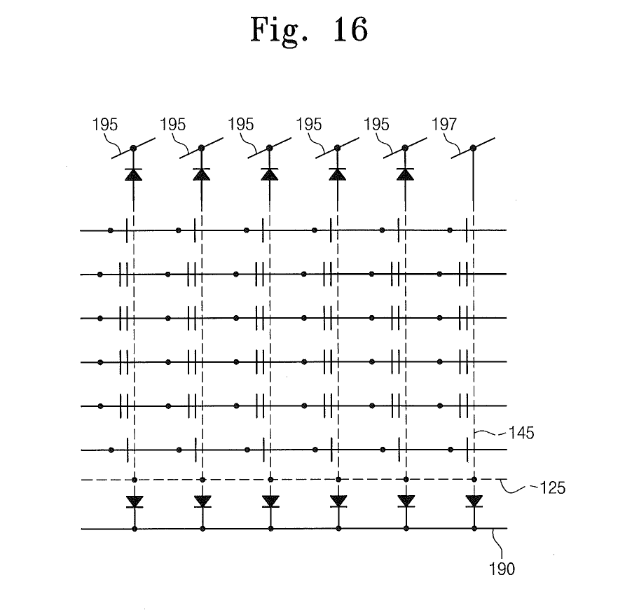

FIG. 15 is a perspective view of a three-dimensional semiconductor memory device in accordance with still another embodiment of the inventive concept. FIG. 16 is a circuit diagram for describing the three-dimensional semiconductor memory device illustrated in FIG. 15.

Referring to FIGS. 15 and 16, in the three-dimensional semiconductor memory device in accordance with the present embodiment, a plurality of vertical semiconductor patterns 145 is two dimensionally arranged on a horizontal semiconductor pattern 125. On the gate structures 170, bit lines 195 are disposed while crossing gate electrodes 171-178 and being connected to the plurality of vertical semiconductor patterns 145. An impurity region D having a different conductivity type from that of the vertical semiconductor pattern 145 may be formed on an upper portion of the vertical semiconductor pattern 145 so as to electrically connect to the bit lines 195. As a result, a PN junction (i.e., diode) may be formed between the vertical semiconductor pattern 145 and the bit line 195. As described with reference to FIG. 10, an upper portion of the horizontal semiconductor pattern 125 may have the same conductivity type as the vertical semiconductor pattern 145 and a lower portion of the horizontal semiconductor pattern 125 may have an opposite conductivity type to the vertical semiconductor pattern 145. In this case, a PN junction may be formed on the horizontal semiconductor pattern 125. Without forming a PN junction on the horizontal semiconductor pattern 125, an electrical connection between the vertical semiconductor pattern 145 and a common source conductive line may be controlled according to whether an inversion layer is formed in the horizontal semiconductor pattern 125 or not.

An interconnection 197 for directly applying a voltage to the horizontal and vertical semiconductor patterns 125 and 145 may be connected to at least one of the vertical semiconductor patterns 145 disposed on the horizontal semiconductor pattern 125. Without forming a drain region in a region where the interconnection 197 and the vertical semiconductor pattern 145 are connected to each other, the interconnection 197 and the vertical semiconductor pattern 145 can be directly connected to each other. Because the horizontal and vertical semiconductor patterns 125 and 145 have the same conductivity type, electric potentials of the horizontal and vertical semiconductor patterns 125 and 145 may be directly controlled through a voltage applied through the interconnection 197 when a semiconductor memory device operates. When the three-dimensional semiconductor memory device in accordance with the present embodiment performs an erasure operation, a ground voltage can be applied to a selected gate electrode 173, 174, 175 or 176 and a positive erasure voltage can be applied to the vertical semiconductor pattern 145. Therefore, data stored in a data storage layer by the Fowler-Nordheim tunneling phenomenon can be erased.

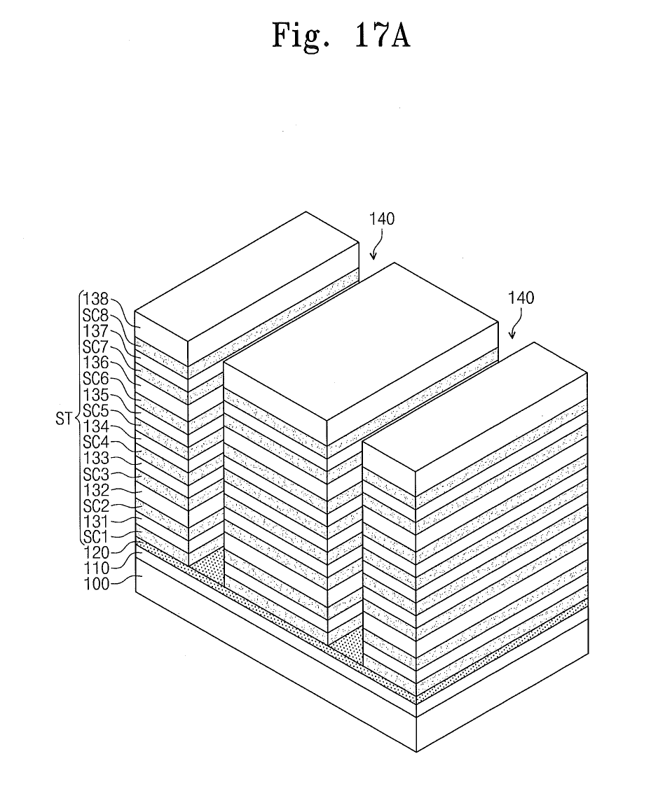

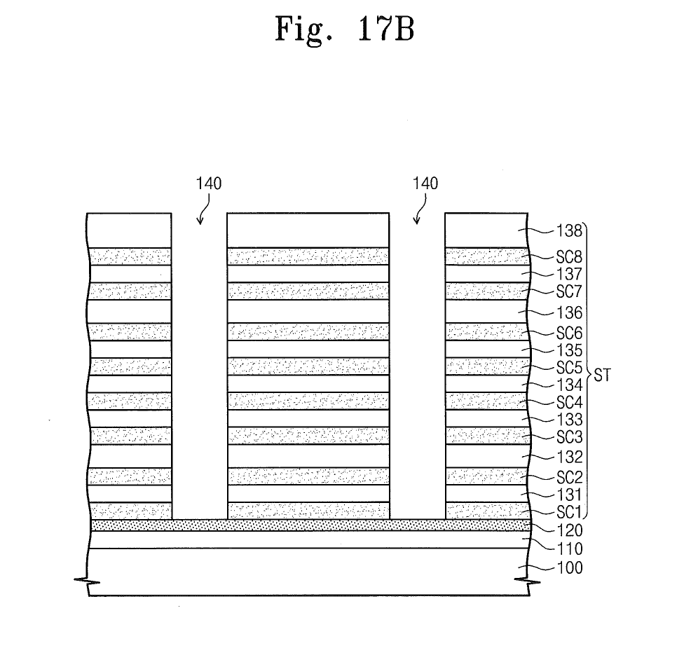

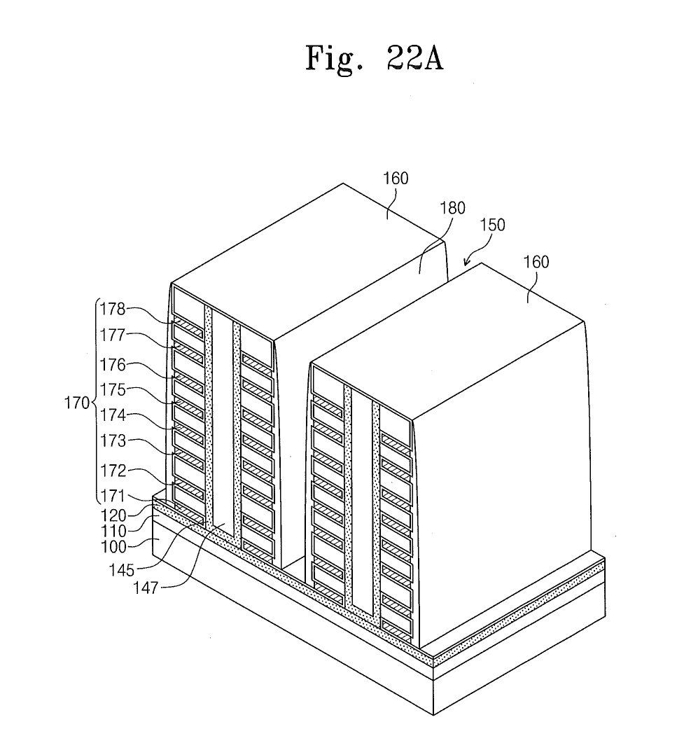

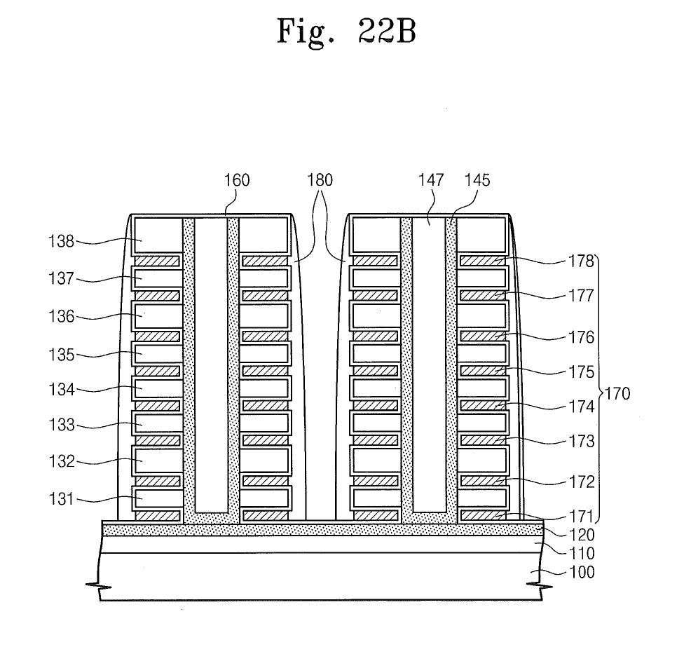

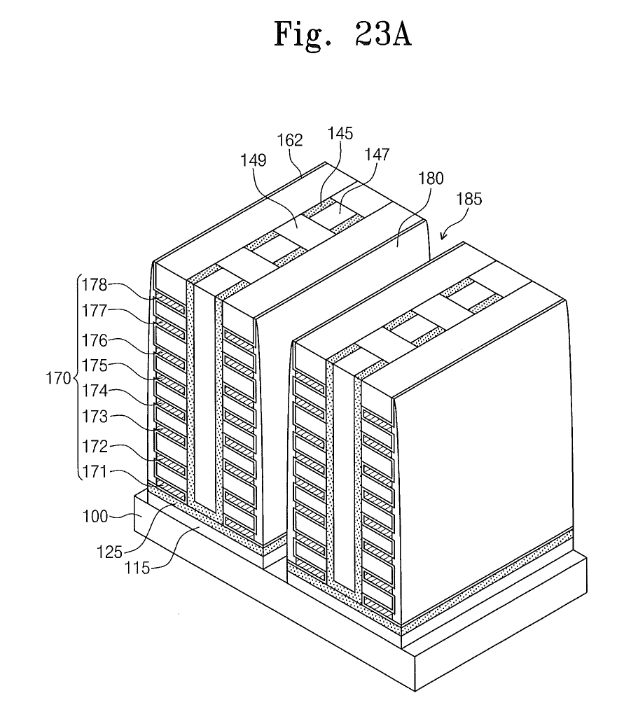

Hereinafter, referring to FIGS. 17A through 26A and FIGS. 17B through 26B, a method of manufacturing a three-dimensional semiconductor memory device in accordance with an embodiment of the inventive concept is described.

FIGS. 17A through 26A are perspective views illustrating a method of manufacturing a three-dimensional semiconductor memory device in accordance with an embodiment of the inventive concept. FIGS. 17B through 26B are cross-sectional views illustrating a method of manufacturing a three-dimensional semiconductor memory device in accordance with an embodiment of the inventive concept.

Referring to FIGS. 17A through 17B, a lower sacrificial layer 110 and a horizontal semiconductor layer 120 are sequentially stacked on a substrate 100.

The substrate 100 may be one of a material having a semiconductor property (e.g., a silicon wafer, a silicon layer, a germanium layer, a silicon germanium layer), an insulating material (e.g., an insulating layer (an oxide, a nitride, etc.), a glass), and a semiconductor covered with an insulating material.

The lower sacrificial layer 110 may be formed from a material having an etching selectivity with respect to the horizontal semiconductor layer 120 and insulating layers 131-138 subsequently formed on the lower sacrificial layer 110. The lower sacrificial layer 110 may be formed using a deposition technology, such as a chemical vapor deposition (CVD) technology or an atomic layer deposition (ALD) technology. A thickness of a common source conductive line 190 may be determined according to a thickness of the lower sacrificial layer 110. The lower sacrificial layer 110 may be selected from, for example, a silicon layer, a silicon oxide layer, a silicon carbide, and a silicon nitride layer, and may be a different material from the insulating layers 131-138.

The horizontal semiconductor layer 120 may be formed from a material having a semiconductor property. For example, the horizontal semiconductor layer 120 may be selected from silicon (Si), germanium (Ge), and combinations thereof. The horizontal semiconductor layer 120 may have a crystal structure including at least one material selected from a single crystalline structure, an amorphous structure and a polycrystalline structure.

The horizontal semiconductor layer 120 may be formed on the lower sacrificial layer 110 by depositing a semiconductor material using a deposition technology, such as a chemical vapor deposition (CVD) technology or an atomic layer deposition (ALD) technology. According to an embodiment, the horizontal semiconductor layer 120 may be formed to be single crystalline silicon by performing a phase change process on amorphous silicon or polycrystalline silicon through a thermal process, such as a laser annealing after depositing amorphous silicon or polycrystalline silicon. According to another embodiment, the horizontal semiconductor layer 120 may be a single crystalline semiconductor formed through an epitaxial growth process using the substrate 100 as a seed. During a formation of the horizontal semiconductor layer 120, the horizontal semiconductor layer 120 may be doped with a first conductivity type impurity and/or a second conductivity type impurity.

According to an embodiment, a thickness of the horizontal semiconductor layer 120, as described above, may be substantially equal to or less than a thickness of an inversion layer formed by a fringing electric field generated from the lowermost layer gate electrode 171 to which a predetermined voltage is applied. According to another embodiment, a thickness of the horizontal semiconductor layer 120 may be greater than a thickness of an inversion layer formed by a fringing electric field generated from the lowermost layer gate electrode 171 to which a predetermined voltage is applied. In this case, when depositing a semiconductor material to form the horizontal semiconductor layer 120, a lower portion of the horizontal semiconductor layer 120 may be doped with a first conductivity type impurity and an upper portion of the horizontal semiconductor layer 120 may be doped with a second conductivity type impurity. Doping the horizontal semiconductor layer 120 with different conductivity type impurities may be performed in-situ while depositing the horizontal semiconductor layer 120. Alternatively, after forming the horizontal semiconductor layer 120 doped with the first conductivity type impurity, an upper portion of the horizontal semiconductor layer 120 may be doped with the second conductivity type impurity. That is, the horizontal semiconductor layer 120, as described with reference to FIG. 10, may include a first conductive region 125a adjacent to the lower sacrificial layer 110 and a second conductive region 125b disposed on the first conductive region 125a.

Subsequently, a thin layer structure ST, such that upper sacrificial layers SC1-SC8 and the insulating layers 131-138 are alternately stacked, is formed on the horizontal semiconductor layer 120.

The insulating layers 131-138 and the upper sacrificial layers SC1-SC8, as illustrated in the drawing, may be alternately and repeatedly stacked. The insulating layers 131-138 and the upper sacrificial layers SC1-SC8 may be formed from a selected material so as to have an etching selectivity. For example, the insulating layers 131-138 may be at least one of a silicon layer, a silicon oxide layer, a silicon carbide, and a silicon nitride layer. The upper sacrificial layers SC1-SC8 may be a different material from the insulating layer selected from a silicon layer, a silicon oxide layer, a silicon carbide layer, and a silicon nitride layer. Also, according to an embodiment, the upper sacrificial layers SC1-SC8 may be formed from the same material as the lower sacrificial layer 110.

According to an embodiment, the upper sacrificial layers (SC1-SC8) may be formed to have a same thickness. Alternatively, according to another embodiment, the lowermost layer upper sacrificial layer SC1 and the uppermost layer upper sacrificial layer SC8 may be formed to be thicker than the upper sacrificial layers SC2-SC7 disposed between the lowermost layer upper sacrificial layer SC1 and the uppermost layer upper sacrificial layer SC8. In this case, the upper sacrificial layers SC2-SC7 disposed between the lowermost layer upper sacrificial layer SC1 and the uppermost layer upper sacrificial layer SC8 may be formed to have a same thickness.

Among the insulating layers 131-138, the insulating layers 132 and 136 formed on predetermined layers, as illustrated in the drawing, may be formed to be thicker than the other insulating layers 131, 133-135 and 138. Also, according to another embodiment, the uppermost insulating layer 139 may be formed to be thicker than the other insulating layers 131-138 disposed under the uppermost insulating layer 139. The insulating layers 131-138 disposed under the uppermost insulating layer 139 may be formed to have a same thickness.

Next, the thin layer structure ST is patterned to form openings 140 exposing the horizontal semiconductor layer 120.

More specifically, forming the openings 140 may include forming a mask pattern (not illustrated) defining a two-dimensional location of the openings 140 on the thin layer structure ST and performing an anisotropic etching on the thin layer structure ST using the mask pattern as an etching mask.

The openings 140 may be formed to expose sidewalls of the upper sacrificial layers SC1-SC8 and the insulating layers 131-138. In a horizontal shape, the openings 140 may be formed in a line shape or a rectangle shape and may be two dimensionally and regularly formed. According to another embodiment, each of the openings 140 may be formed in a cylindrical shape or a rectangular shape. The opening 140 may have a different width according to a distance from the substrate 100 by an anisotropic etching process.

According to an embodiment, the openings 140 may be formed to expose a top surface of the horizontal semiconductor layer 120. While forming the openings 140, a top surface of the horizontal semiconductor layer 120 exposed by the opening 140 may be recessed to have a predetermined depth by an over etching. According to another embodiment, the openings 140 may penetrate the horizontal semiconductor layer 120 to expose a top surface of the lower sacrificial layer 110.

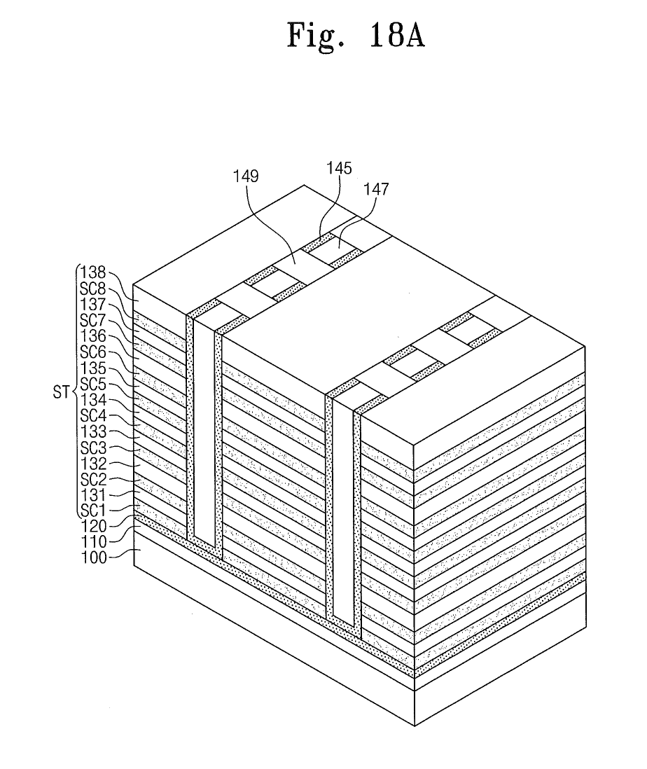

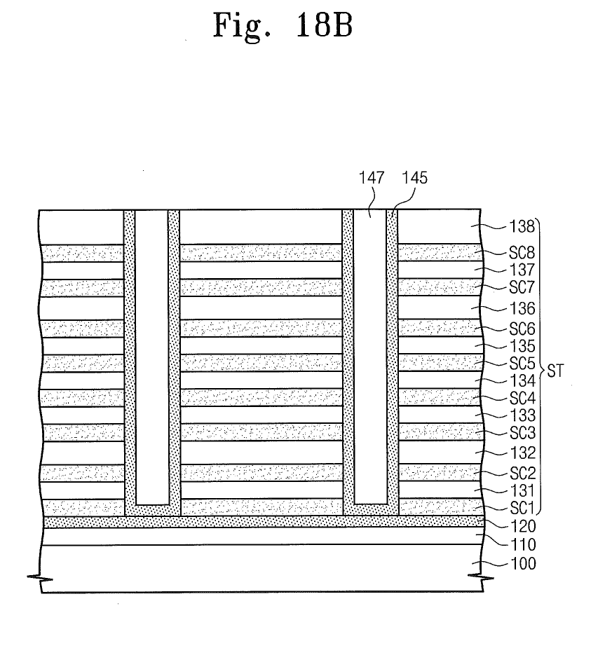

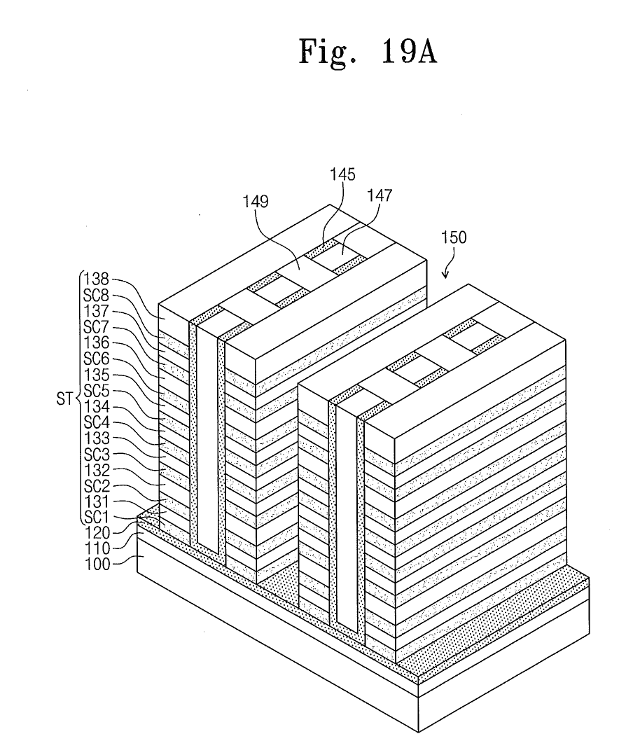

Referring to FIGS. 18A and 18B, vertical semiconductor patterns 145 are formed in the openings 140. The vertical semiconductor patterns 145 may be formed in the openings 140 using a chemical vapor deposition (CVD) technology or an atomic layer deposition (ALD) technology. Accordingly, the vertical semiconductor pattern 145 is conformally formed in the opening 140 to be directly in contact with the horizontal semiconductor pattern 120 and to be substantially perpendicular to the horizontal semiconductor pattern 120. At this time, the vertical semiconductor pattern 145 may be deposited to have a thickness equal to or less than half of a width of the opening 140. In this case, the vertical semiconductor pattern 145 may fill a portion of the opening 140 to define a vacant region at a center of the opening 140. Also, a thickness of the vertical semiconductor pattern 145 (i.e., a thickness of shell) may be less than a depletion region to be formed therein or may be smaller than an average length of silicon grains constituting polycrystalline silicon.

That is, the vertical semiconductor pattern 145 may be formed in a shape of a hollow cylindrical type, a cup or a U character. The vacant region defined by the vertical semiconductor pattern 145 may be filled with a buried insulating pattern 147. The buried insulating pattern 147 may be formed of an insulating material having a superior gap-fill characteristic. For example, the buried insulating pattern 147 may be formed of a high density plasma oxide layer, a spin on glass (SOG) layer and/or a chemical vapor deposition (CVD) oxide layer. According to another embodiment, the opening 140 can be completely filled with the vertical semiconductor pattern 145 by a deposition process. In this case, after depositing the vertical semiconductor pattern 145, a planarization process may be performed on the vertical semiconductor pattern 145.

The vertical semiconductor pattern 145 may include, for example, silicon (Si), germanium (Ge) or combinations thereof. The vertical semiconductor pattern 145 may be formed to have the same conductivity type as the horizontal semiconductor layer 120, which is in contact with the vertical semiconductor pattern 145. Also, the horizontal semiconductor layer 120 may have a crystal structure including at least one selected from a single crystalline, an amorphous and a polycrystalline. In the case of forming the vertical semiconductor pattern 145 using a deposition technology, a discontinuous interface may be formed between the vertical semiconductor pattern 145 and the horizontal semiconductor layer 120. According to an embodiment, the vertical semiconductor pattern 145 may be formed to be single crystalline silicon by performing a phase change of amorphous silicon or polycrystalline silicon through a thermal process, such as a laser annealing after depositing amorphous silicon or polycrystalline silicon. According to another embodiment, the vertical semiconductor pattern 145 may be formed in the opening 140 by performing an epitaxial process using the horizontal semiconductor layer 120 exposed by the opening 140 as a seed layer.

According to an embodiment, forming the vertical semiconductor pattern 145 may include patterning the vertical semiconductor layer after forming a vertical semiconductor layer and buried insulating layers sequentially filling the openings 140 of a line shape. That is, after forming a plurality of vertical semiconductor patterns 145 separated from one another in the openings 140 of a line shape, buried insulating patterns 149 filling a space between the vertical semiconductor patterns 145 may be further formed.

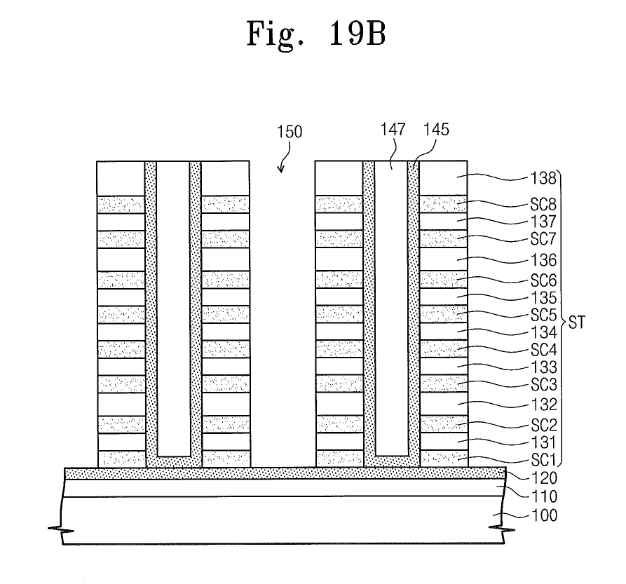

Referring to FIGS. 19A and 19B, upper trenches 150 exposing the horizontal semiconductor layer 120 are formed between the adjacent vertical semiconductor patterns 145.

More specifically, forming the upper trenches 150 may include forming a mask pattern (not illustrated) defining a two-dimensional location of the upper trenches 150 on the thin layer structure ST and anisotropically etching the thin layer structure ST using the mask pattern as an etching mask.

The upper trench 150 may be formed to be spaced apart from the vertical semiconductor patterns 145 and to expose sidewalls of the upper sacrificial layers SC1-SC8 and the insulating layers 131-138. In a horizontal shape, the upper trench 150 may be formed in a line shape or a rectangular shape and in a vertical depth, the upper trench 150 may be formed to expose a top surface of the horizontal semiconductor layer 120. Thus, the thin layer structures ST may have a line shape parallel to each other. A plurality of vertical semiconductor patterns 145 may penetrate one thin layer structure ST and may have a line shape.

The upper trench 150 may have a different width according to a distance from the substrate 100 by an anisotropic etching process. Also, during a formation of the upper trenches 150, a top surface of the horizontal semiconductor layer 120 exposed to the upper trench 150 may be recessed to a predetermined depth by an over etching.

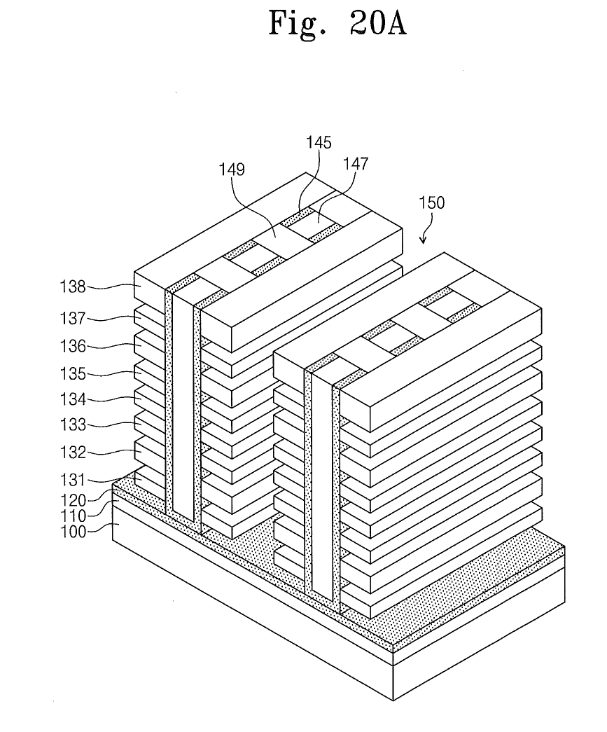

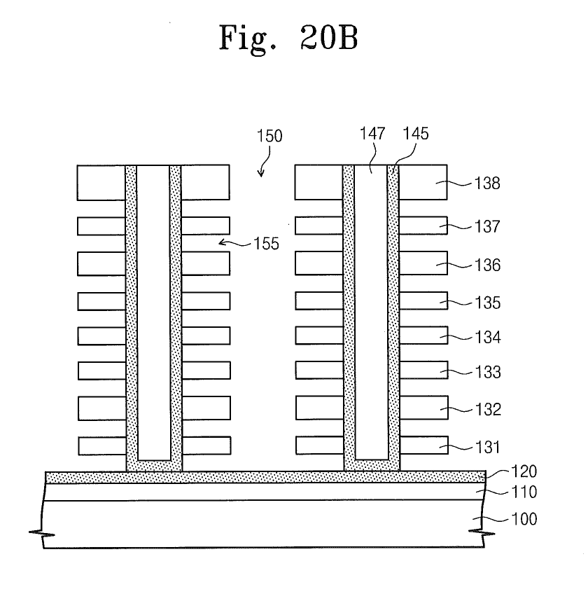

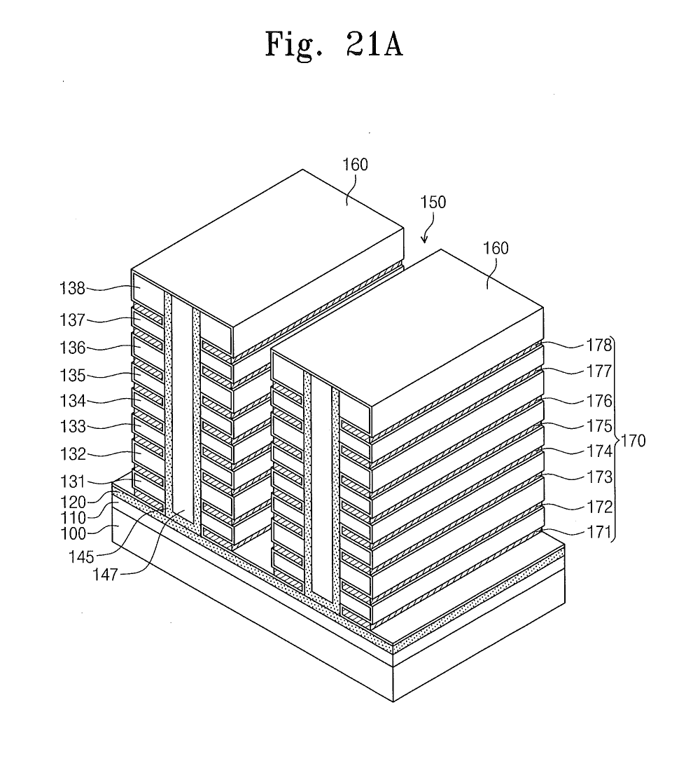

Referring to FIGS. 20A and 20B, the upper sacrificial layers SC1-SC8 exposed by the upper trenches 150 are removed to form recess regions 155 between the insulating layers 131-138.

The recess regions 155 may horizontally extend between the insulating layers 131-138 from the upper trench 150 and may expose a portion of the sidewall of the vertical semiconductor pattern 145. Forming the recess region 155 may include isotropically etching the upper sacrificial layers SC1-SC8 using an etching recipe with respect to the insulating layers 131-138. Here, the upper sacrificial layers SC1-SC8 may be completely removed by the isotropic etching process. For example, in the case that the upper sacrificial layers SC1-SC8 are silicon nitride layers and the insulating layers 131-138 are silicon oxide layers, an etching may be performed using an etching solution including phosphoric acid.

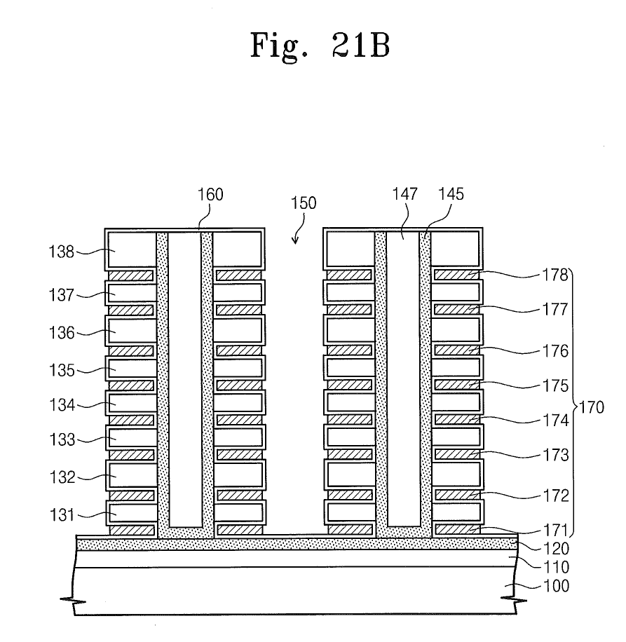

Referring to FIGS. 21A and 21B, a data storage layer 160 is formed in the recess regions 155.

The data storage layer 160 may be formed using a deposition technology (e.g., a chemical vapor deposition (CVD) technology or an atomic layer deposition (ALD) technology), which can provide a superior step difference coating characteristic. The data storage layer 160 may be formed to have a thickness less than half of a thickness of the recess region 155. Thus, the data storage layer 160 may be formed to substantially cover the thin layer structure ST including the recess regions 155. That is, the data storage layer 160 may be formed on sidewalls of the vertical semiconductor pattern 145 exposed by the recess regions 155 and the data storage layer 160 may extend in top and bottom surfaces of the insulating layers 131-138 defining the recess region 155. Also, the data storage layer 160 may be formed in a line shape on a top surface of the horizontal semiconductor layer 120 exposed between the thin layer structures ST.

According to an embodiment, the data storage layer 160 may include a charge storage layer. For example, the data storage layer 160 may include one of a trap insulating layer, a gate electrode, or an insulating layer including conductive nano dots.

According to an embodiment, the data storage layer 160 may include a blocking insulating layer, a charge trap layer, and a tunnel insulating layer that are sequentially stacked. The blocking insulating layer may include at least one of a silicon oxide layer, a silicon nitride layer, a silicon oxynitride layer, and a high dielectric layer and may be comprised of a plurality of layers. At this time, a high dielectric layer means an insulating material having a dielectric constant greater than a silicon oxide layer and may include a tantalum oxide layer, a titanium oxide layer, a hafnium oxide layer, a zirconium oxide layer, an aluminum oxide layer, a yttrium oxide layer, a niobium oxide layer, a cesium oxide layer, an indium oxide layer, an iridium oxide layer, a BST layer, and/or a PZT layer. The tunnel insulating layer may be formed to have a dielectric constant lower than the blocking insulating layer. The charge trap layer may be an insulating thin layer (e.g., a silicon nitride layer) having abundant charge trap sites or an insulating thin layer having conductive grains. According to an embodiment, the tunnel insulating layer may be a silicon oxide layer, the trap layer may be a nitride layer, and the blocking insulating layer may be an insulating layer including an aluminum oxide layer.

Subsequently, gate electrodes 171-178 are formed in the recess regions 155 where the data storage layer 160 is formed.

Forming the gate electrodes 171-178 includes forming a gate conductive layer in the recess regions 155 where the data storage layer 160 is formed and the upper trench 150, and removing the gate conductive layer in the upper trench 150 to form the gate electrodes 171-178 so as to be vertically separated from each other.

The gate conductive layer may be formed using a deposition technology (e.g., a chemical vapor deposition (CVD) technology or an atomic layer deposition (ALD) technology), which can provide a superior step difference coating characteristic. Therefore, the gate conductive layer may be conformally formed in the upper trench 150 while filling the recess regions 155. More specifically, the gate conductive layer may be deposited to have a thickness equal to or greater than half of the recess region 155. In the case that a two-dimensional width of the upper trench 150 is greater than a thickness of the recess region 155, the gate conductive layer may fill a portion of the upper trench 150 and may define a vacant region at the center of the upper trench 150. At this time, the vacant region may have an open upper portion thereof.

The gate conductive layer may include at least one of doped silicon, tungsten, metal nitride layers, and metal silicides. Because the inventive concept is not limited to a flash memory device, the gate conductive layer may vary in material and structure.

According to an embodiment, forming the gate electrodes 171-178 includes reforming the upper trench 150 by anisotropically etching the gate conductive layer filling the upper trench 150. More specifically, removing the gate conductive layer in the upper trench 150 may include anisotropically etching the gate conductive layer using the uppermost insulating layer constituting the thin layer structure ST or a hard mask pattern (not illustrated) additionally formed on the uppermost insulating layer as an etching mask. When anisotropically etching the gate conductive layer, the data storage layer which is in contact with a top surface of the horizontal semiconductor layer 120 may be used as an etch stop layer. Alternatively, as the gate conductive layer is anisotropically etched, a top surface of the horizontal semiconductor layer 120 may be exposed by the upper trench 150.

According to another embodiment, the gate electrodes 171-178 may be formed by performing an isotropic etching process on the gate conductive layer including a vacant region. An isotropic etching process may be performed until the gate electrodes 171-178 are separated from one another. That is, sidewalls of the insulating layers 131-138 and the data storage layer 160 on a top surface of the horizontal semiconductor layer 120 may be exposed by an anisotropic etching process. Here, as the isotropic etching process is performed through the vacant region, the gate conductive layer of a sidewall and a bottom surface of the vacant region may be simultaneously etched. As the isotropic etching process is performed through the vacant region, the gate conductive layer on upper portions of the thin layer structure and the horizontal semiconductor layer 120 may be uniformly etched. Thus, a horizontal thickness of the gate electrodes 171-178 may be generally uniform. When an isotropic etching process is performed, a horizontal thickness of the gate electrodes 171-178 may be different according to a process time. For example, the gate electrodes 171-178 may be formed to fill a portion of the recess region 155.

The gate electrodes 171-178 locally formed in the recess regions may constitute a gate structure 170. That is, the gate structure 170 may be formed between the adjacent upper trenches 150. The gate electrodes 171-178 have outer sidewalls adjacent to the upper trench 150 and inner sidewalls adjacent to the vertical semiconductor pattern 145.

According to another embodiment, after forming the gate structure 170, a process of selectively removing sidewalls of the insulating layers 131-138 and the data storage layer 160 formed on a surface of the horizontal semiconductor layer 120 may be further performed. A process of removing the data storage layer 160 may use an etching gas or an etching solution having an etching selectivity with respect to the gate conductive layer. For example, in the case of removing the data storage layer 160 on sidewalls of the insulating layers 131-138 through an isotropic etching process, an etching solution, such as HF, O3/HF, phosphate acid, sulfuric acid and/or LAL may be used. Also, to remove the data storage layer 160, an etching solution of fluoride system, and phosphate acid or sulfuric acid may be sequentially used.

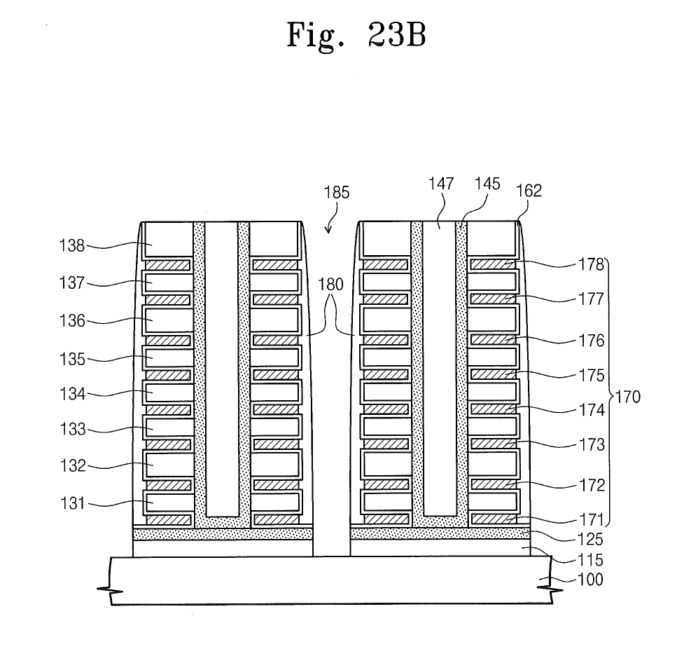

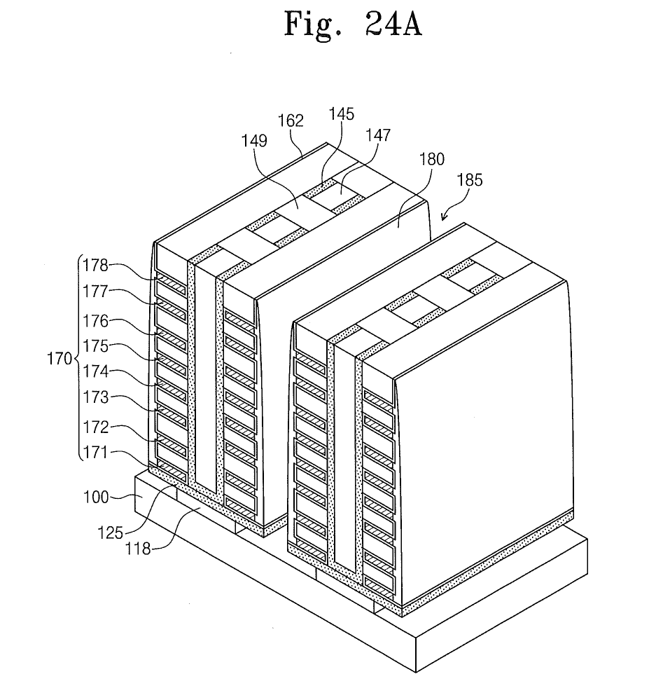

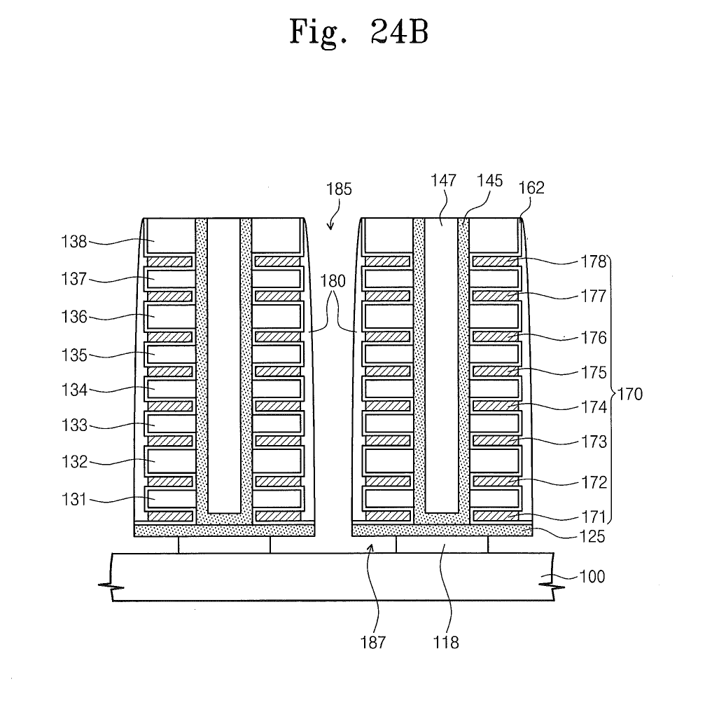

After forming the gate structure 170, a common source conductive line is formed between the substrate 100 and the horizontal semiconductor layer 120. Forming the common source conductive line may include forming a lower trench 185 extending from the upper trench 150 by patterning the horizontal semiconductor layer 120 and the lower sacrificial layer as illustrated in FIGS. 23A and 23B and replacing a portion of the lower sacrificial layer 110 with a metal material layer as illustrated in FIGS. 24A and 24B.

To form the lower trench 185, as illustrated in FIGS. 23A and 23B, a spacer 180 covering a sidewall of the gate structure 170 may be formed on the data storage layer 160 or the horizontal semiconductor layer 120.

The spacer 180 may be formed on an outer sidewall of the gate structure 170 by conformally forming an insulating layer along a surface of the gate structure 170, and then anisotropically etching the insulating layer. That is, the spacer 180 covers sidewalls of the gate electrodes 171-178 exposed to the upper trench 150. The spacer 180 can reduce an etching damage to the data storage layer 160 during a patterning process of etching the data storage layer 160.

According to an embodiment, the spacer 180 may be formed from an insulating material having an etching selectivity with respect to the gate electrodes 171-178 and the data storage layer 160. For example, the spacer 180 may be formed from a material selected from a silicon oxide layer, a silicon nitride layer, a silicon oxynitride layer, and a silicon carbide layer.

Forming the lower trench 185, as illustrated in FIGS. 23A and 23B, may include anisotropically etching the horizontal semiconductor layer 120 and the lower sacrificial layer using the gate structure 170 and the spacer 180 as an etching mask. The lower trench 185 can extend from the upper trench 150 to expose a top surface of the substrate 100. Also, during a formation of the lower trench 185, a top surface of the substrate 100 exposed by the lower trench 185 may be recessed to have a predetermined depth by an over etching. By forming the lower trench 185, a horizontal semiconductor pattern 125 and a lower sacrificial layer pattern 115 may be formed under each of the gate structures 170 so as to have a line shape by the upper trenches 150.

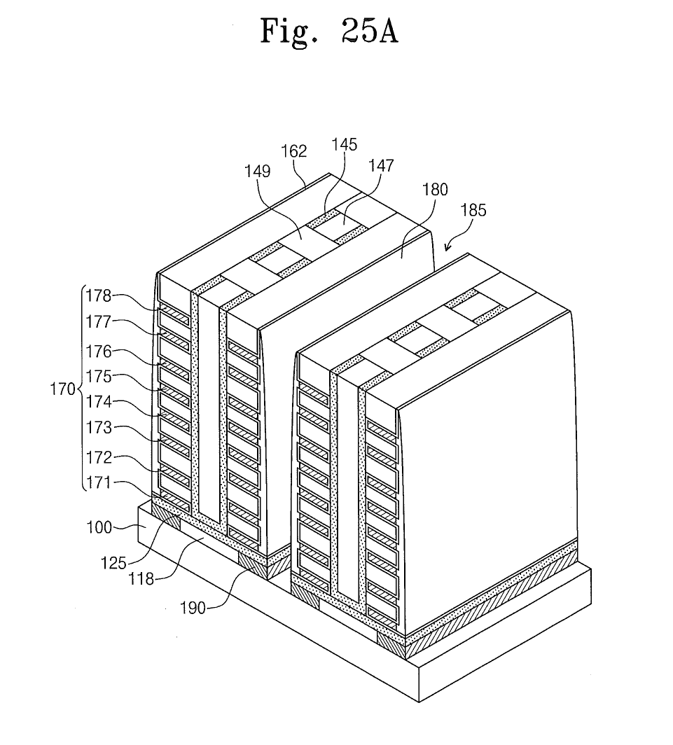

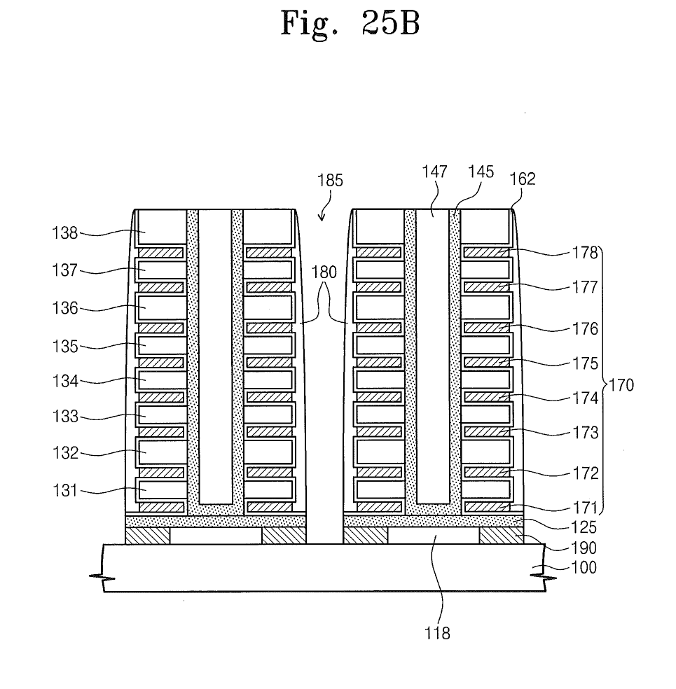

Replacing a portion of the lower sacrificial layer 110 with a metal material layer may include forming a lower recess region 187 by removing a portion of the lower sacrificial layer pattern 115 exposed to the lower trench 185 as illustrated in FIGS. 24A and 24B and forming the common source conductive line 190 in the lower recess region 187 as illustrated in FIGS. 25A and 25B.

More specifically, forming the lower recess region 187 may include isotropically etching the lower sacrificial layer pattern 115 using an etching recipe having an etching selectivity with respect to the horizontal semiconductor layer 120, the insulating layers 131-138, and the spacer 180. Here, a portion of the lower sacrificial layer pattern 115 may be removed by isotropic etching. For example, in the case that the lower sacrificial layer pattern 115 is a silicon nitride layer, and the insulating layers 131-138 and the spacer 180 are a silicon oxide layer, an isotropic etching process may be performed using an etching solution including phosphate acid. As an isotropic etching process is performed, the lower recess region 187 horizontally extending from the lower trench 185 may be formed. A horizontal width of the lower recess region 187 may be determined by the amount of etching of the lower sacrificial layer pattern 115 removed by an isotropic etching process. The lower recess region 187 may expose a portion of a bottom surface of the horizontal semiconductor pattern 125 under the gate electrodes 171-178.

An isotropic etching process may be performed in such a manner that the gate structure 170 formed on the lower sacrificial layer pattern 115 does not collapse. That is, as the lower recess region 187 is formed, a portion of bottom surface of the horizontal semiconductor pattern 125 may be exposed and a support pattern 118, which is a remaining lower sacrificial layer pattern 115, may be formed between the horizontal semiconductor pattern 125 and the substrate 100.

Referring to FIGS. 25A and 25B, the common source conductive line 190 is formed in the lower recess region 187.

More specifically, forming the common source conductive line 190 may include forming a conductive layer filling the lower recess region 187 and the lower and upper trenches 185 and 150. Here, the conductive layer may be formed using a deposition technology having a superior step difference coating characteristic. Thus, the conductive layer can be directly in contact with a bottom surface of the horizontal semiconductor pattern 125. The conductive layer for forming the common source conductive line 190 may be deposited as far as an upper portion of the gate structure 170 and may be buried between the gate structures 170 by planarizing the conductive layer so that the uppermost insulating layer is exposed. Also, the conductive layer may have a structure extending between the gate structures 170 from a lower portion of the gate structure 170. The conductive layer filling a space between the gate structures (i.e., the lower and upper trenches 185 and 150) may be separated from the gate electrodes 171-178 by the spacer 180.

The common source conductive line 190 may include at least one material selected from metal (e.g., tungsten, titanium, tantalum, tantalum aluminum, etc.), conductive metal nitrides (e.g., titanium nitride, tantalum nitride, etc.), and metal silicides (e.g., tungsten silicide, cobalt silicide, titanium silicide, nickel silicide, etc.). According to an embodiment, the common source conductive line 190 may be formed by forming conductive metal nitride, which is a metal barrier material, and then depositing metal. As illustrated in FIG. 9, the conductive metal nitride may be directly in contact with a bottom surface of the horizontal semiconductor pattern 125.

After forming a conductive layer in the lower and upper trenches 185 and 150, the conductive layer filling the lower and upper trenches 185 and 150 may be removed to locally form the common source conductive line 190 in the lower recess regions. That is, removing the conductive layer may include reforming the lower and upper trenches 185 and 150 between the gate structures 170 to expose a top surface of the substrate 100. More specifically, removing the conductive layer may include anisotropically etching the conductive layer using the uppermost insulating layer 138 constituting the thin layer structure ST or a hard mask pattern (not illustrated) additionally formed on the uppermost insulating layer 139 as an etching mask.

According to another embodiment, as illustrated in FIG. 7, the common source conductive line 190 may extend from a lower portion of the gate structure 170 to a lower portion of adjacent gate structure 170.

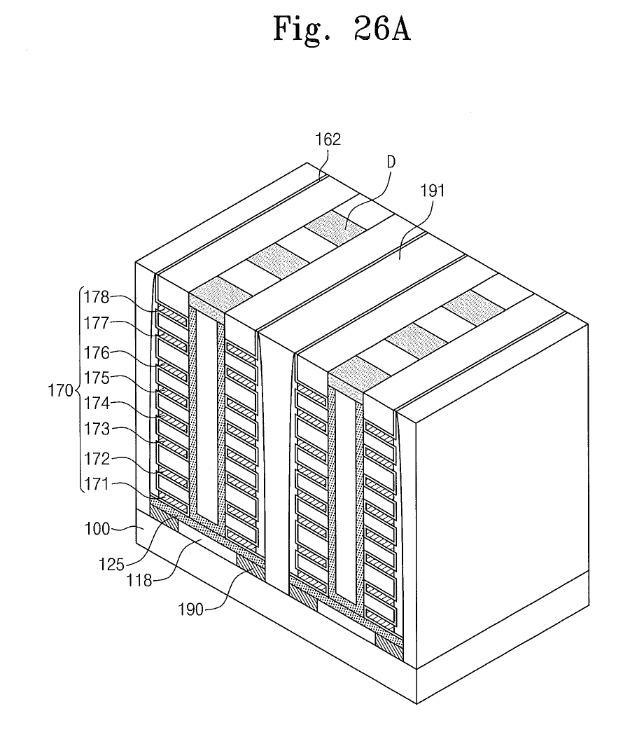

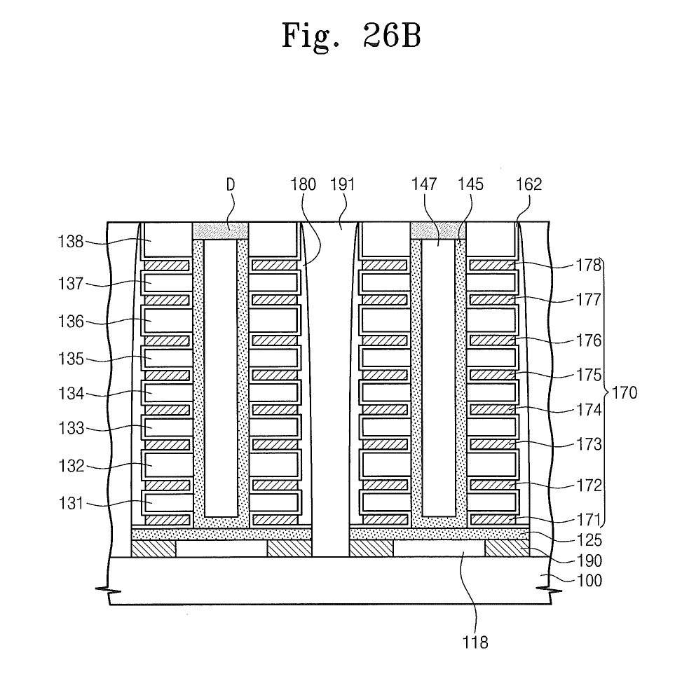

Subsequently, referring to FIGS. 26A and 26B, a gate separation insulating pattern 191 is formed in the lower and upper trenches 185 and 150.

Forming the gate separation insulating pattern 191 may include filling the lower and upper trenches 185 and 150 from which the conductive layer is removed with one or more insulating materials. According to an embodiment, the gate separation insulating pattern 191 may be at least one of a silicon oxide layer, a silicon nitride layer, and a silicon oxynitride layer. According to an embodiment, the gate separation insulating pattern 191 may be formed of the same material as the spacer 180 on a sidewall of the gate structure 170.

According to an embodiment, at a space between the gate structures 170, the gate separation insulating pattern 191 may extend in a space between adjacent common source conductive lines 190 to be directly in contact with the substrate 100. According to another embodiment, the gate separation insulating pattern 191 may be formed on the common source conductive line 190.

After forming the common source conductive line 190, an impurity having a conductivity type opposite to the vertical semiconductor pattern 145 is implanted into an upper portion of the vertical semiconductor pattern 145 to form a drain region D. According to another embodiment, the drain region D, as illustrated in FIG. 19, may be formed on an upper portion of the vertical semiconductor pattern 145 before forming the upper trench 150.

After forming the common source conductive line 190, bit lines 195 electrically connecting the vertical semiconductor patterns 145 may be formed on an upper portion of the gate structure 170. The bit lines 195, as illustrated, may be formed in a line shape along a direction crossing the gate structure 170. The bit lines 195 may be connected to the drain region D on the vertical semiconductor pattern 145.

FIGS. 27 through 33 are cross-sectional views illustrating a method of manufacturing a three-dimensional semiconductor memory device in accordance with the embodiment illustrated in FIGS. 13 and 14.

Referring to FIG. 27, as described with reference to FIG. 17, a lower sacrificial layer 110 and a horizontal semiconductor layer 120 are sequentially stacked on a substrate 100.

The lower sacrificial layer 110 may be formed from a material having an etching selectivity with respect to the horizontal semiconductor layer 120, the substrate 100, and insulating layers 132-139 to be formed on the lower sacrificial layer 110. The lower sacrificial layer 110 may be formed using a deposition technology, such as a chemical vapor deposition (CVD) technology or an atomic layer deposition (ALD) technology. A thickness of the lower sacrificial layer 110 may be determined based on a thickness of a common source conductive line 190 to be formed in a subsequent process. The lower sacrificial layer 110 may be formed from an insulating material such as, for example, a silicon layer, a silicon oxide layer, a silicon carbide and a silicon nitride layer, and may be formed from a different material from the insulating layers 132-139.

The horizontal semiconductor layer 120 may be formed from a material having a semiconductor property. For example, the horizontal semiconductor layer 120 may be selected from silicon (Si), germanium (Ge), and combinations thereof. The horizontal semiconductor layer 120 may have a crystal structure including at least one material selected from a single crystalline structure, an amorphous structure, and a polycrystalline structure.

The horizontal semiconductor layer 120 may be formed on the lower sacrificial layer 110 by depositing a semiconductor material using a deposition technology, such as a chemical vapor deposition (CVD) technology or an atomic layer deposition (ALD) technology. During a formation of the horizontal semiconductor layer 120, the horizontal semiconductor layer 120 may be doped with an n-type impurity and/or a p-type impurity. According to an embodiment, the horizontal semiconductor layer 120 may be formed to be single crystalline silicon by performing a phase change process on amorphous silicon or polycrystalline silicon through a thermal process, such as a laser annealing after depositing amorphous silicon or polycrystalline silicon. According to another embodiment, the horizontal semiconductor layer 120 may be a single crystalline semiconductor formed through an epitaxial growth process using the substrate 100 as a seed.

A thickness of the horizontal semiconductor layer 120, as described with reference to FIGS. 17A and 17B, may be substantially equal to or less than a thickness of an inversion layer formed by a fringing electric field generated from the lowermost layer gate electrode GP1 to which a predetermined voltage is applied. According to another embodiment, a thickness of the horizontal semiconductor layer 120 may be greater than a thickness of an inversion layer formed by a fringing electric field generated from the lowermost layer gate electrode GP1 to which a predetermined voltage is applied. In this case, when depositing a semiconductor material, a lower portion of the horizontal semiconductor layer 120 may be doped with a first conductivity type impurity and an upper portion of the horizontal semiconductor layer 120 may be doped with a second conductivity type impurity opposite to the first conductivity type. Doping the horizontal semiconductor layer 120 with different conductivity type impurities may be performed in-situ while depositing the horizontal semiconductor layer 120. Alternatively, after forming the horizontal semiconductor layer 120 of which an entire portion is doped with the first conductivity type impurity, an upper portion of the horizontal semiconductor layer 120 may be doped with the second conductivity type impurity. That is, the horizontal semiconductor layer 120 may include a first conductive region 125a adjacent to the lower sacrificial layer 110 and a second conductive region 125b disposed on the first conductive region 125a.

Subsequently, in contrast with the embodiments described with reference to FIGS. 17A and 17B, a thin layer structure such that the gate conductive layers GP1-GP8 and the insulating layers 132-139 are alternately stacked is formed on the horizontal semiconductor layer 120.

The insulating layers 132-139 may be at least one of a thermal oxide layer, a silicon oxide layer, a silicon nitride layer, and a silicon oxynitride layer. The gate conductive layers GP1-GP8 are formed from one or more conductive materials so that the gate conductive layers GP1-GP8 are used as gate electrodes. For example, the gate conductive layers GP1-GP8 may include at least one of doped polysilicon, a metal layer, metal nitride layers, and metal silicides.

Before forming the gate conductive layers GP1-GP8 and the insulating layers 132-139 on the horizontal semiconductor layer 120, a buffer dielectric layer 131 may be formed on the horizontal semiconductor layer 120. The gate conductive layers GP1-GP8 and the insulating layers 132-139 may be formed on the buffer dielectric layer 131. The buffer dielectric layer 131 may be directly in contact with the lowermost gate conductive layer GP1 and may be formed from a dielectric material having an etching selectivity with respect to the gate conductive layers GP1-GP8. For example, the buffer dielectric layer 131 may be formed from an oxide, such as a thermal oxide.

According to embodiments of the present embodiment, the gate conductive layers GP1 and GP2 located at a lower portion of the thin layer structure may be used as the ground select lines GSL0-GSL2 described with reference to FIG. 1 and the gate conductive layers GP7 and GP8 located at an upper portion of the thin layer structure may be used as the string select lines SSL described with reference to FIG. 1. The rest of the gate conductive layers GP3-GP6 may be used as the word lines (WL) described with reference to FIG. 1.

A thickness of the gate conductive layers GP3-GP6 used as gate electrodes of memory cell transistors in accordance with embodiments of the inventive concept determines a channel length of the memory cell transistor. According to an embodiment, because the gate conductive layers GP1-GP8 are formed using a deposition process, a channel length may be more precisely controlled compared with the case of forming the gate conductive layers GP1-GP8 using a patterning technology. Also, because a lengthwise direction of channels of a memory cell transistor is perpendicular to the substrate 100, an integration of the semiconductor memory device in accordance with the inventive concept is independent of a thickness of the gate conductive layers GP1-GP8. As described above, a space (i.e., a thickness of the insulating layers 132-139) between the gate conductive layers GP1-GP8 used as gate electrodes of memory cell transistors may be formed to have a range smaller than a maximum width of an inversion area formed in a vertical semiconductor pattern 145 to be formed later.

The ground select line GSL0-GSL2 and the string select line SSL described in FIG. 1, as illustrated in the drawing, may comprise a plurality of vertically adjacent gate conductive layers. According to another embodiment, the lower and upper gate conductive layers GP1 and GP8 used as the ground select line GSL0-GSL2 and the string select line SSL0-SSL2 may be formed to be thicker than the other gate conductive layers GP2-GP7.

The number of thin layers, a thickness of each of thin layers, and a material of each of the thin layers that constitute a thin layer structure may diversely vary based on an electrical characteristic of memory cell transistor and a technical difficulty in a process of patterning the thin layers.

Referring to FIG. 27, the thin layers are patterned to form openings 140 exposing the horizontal semiconductor layer 120.

More specifically, forming the openings 140 may include forming a mask pattern (not illustrated) defining a two-dimensional location of the openings 140 on the thin layer structure and performing an anisotropic etching on the thin layer structure using the mask pattern as an etching mask.

The openings 140 may be formed to expose sidewalls of the gate conductive layers GP1-GP8 and the insulating layers 132-139. In a horizontal view, the openings 140 may be formed in cylindrical shape or the hole shape may be rectangular and may be two dimensionally and regularly formed. The opening 140 may have a different width according to a distance from the substrate 100 by an anisotropic etching process. Also, the openings 140 may be formed in a line shape or a rectangle shape.

According to an embodiment, the openings 140 may be formed to expose a top surface of the horizontal semiconductor layer 120. While forming the openings 140, a top surface of the horizontal semiconductor layer 120 exposed by the opening 140 may be recessed to have a predetermined depth by an over etching. According to another embodiment, the openings 140 may penetrate the horizontal semiconductor layer 120 to expose a top surface of the lower sacrificial layer 110. Even in this case, a top surface of the horizontal semiconductor layer 120 exposed by the opening 140 may be recessed to have a predetermined depth by an anisotropic etching forming the openings 140. According to still another embodiment, the openings 140 may penetrate the thin structure, the horizontal semiconductor layer 120 and the lower sacrificial layer 110 to expose a top surface of the substrate 100.

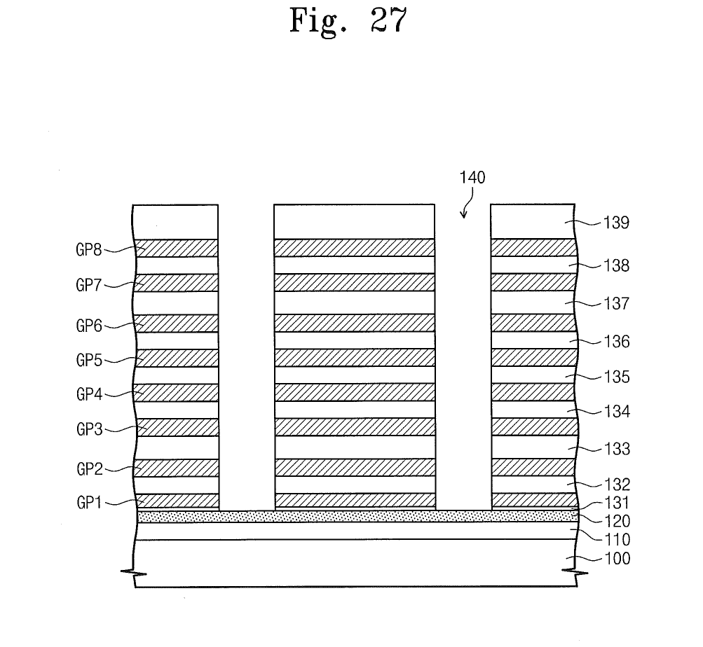

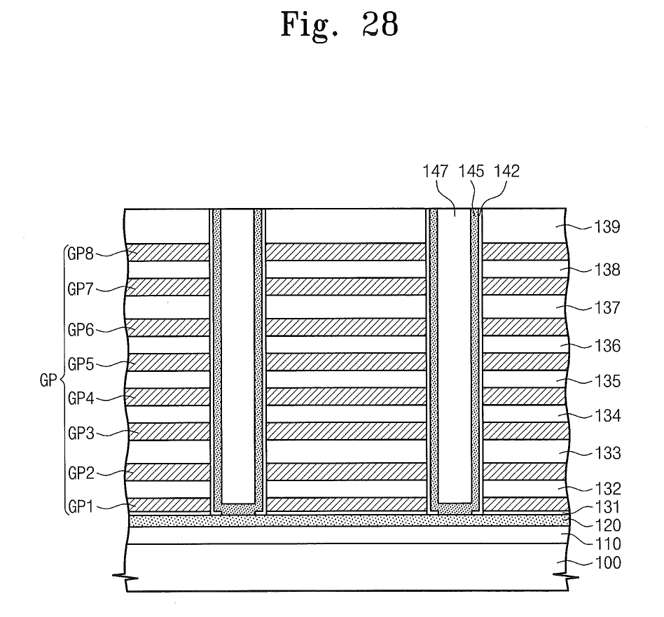

Referring to FIG. 28, a data storage layer 142 and a vertical semiconductor pattern 145 are formed in the openings 140.

The data storage layer 142 may be formed using a deposition technology (e.g., a chemical vapor deposition (CVD) technology or an atomic layer deposition (ALD) technology), which can provide a superior step difference coating characteristic. The data storage layer 142 may be formed to have a thickness less than half of a width of the opening 140. Thus, the data storage layer 142 may substantially cover one of the sidewalls of the gate conductive layers GP1-GP8 and the insulating layers 132-139 exposed by the opening 140. Because the data storage layer 142 is formed using a deposition technology, the data storage layer 142 may be conformally deposited on a top surface of the horizontal semiconductor layer 120 exposed by the opening 140.

According to an embodiment of the inventive concept for a flash memory, the data storage layer 142 may include a charge storage layer. For example, the charge storage layer may include at least one of a charge trap insulating layer, a floating gate electrode, and an insulating layer including conductive nano dots.

According to an embodiment, the data storage layer 142 may include a blocking insulating layer, a charge trap layer, and a tunnel insulating layer that are sequentially stacked. The blocking insulating layer may include at least one of a silicon oxide layer, a silicon nitride layer, a silicon oxynitride layer, and a high dielectric layer and may be comprised of a plurality of layers. At this time, the high dielectric layer means an insulating material having a dielectric constant higher than a silicon oxide layer and may include a tantalum oxide layer, a titanium oxide layer, a hafnium oxide layer, a zirconium oxide layer, an aluminum oxide layer, a yttrium oxide layer, a niobium oxide layer, a cesium oxide layer, an indium oxide layer, an iridium oxide layer, a BST layer, and/or a PZT layer. The tunnel insulating layer may be formed from a material having a dielectric constant lower than the blocking insulating layer. The charge trap layer may be an insulating thin layer (e.g., a silicon nitride layer) having abundant charge trap sites or an insulating thin layer having conductive grains. According to an embodiment, the tunnel insulating layer may be a silicon oxide layer, the trap layer may be a nitride layer and the blocking insulating layer may be an insulating layer including an aluminum oxide layer.

The vertical semiconductor pattern 145 formed in the opening 140 may be electrically connected to the horizontal semiconductor layer 120. Thus, before forming the vertical semiconductor pattern 145 in the opening 140, the data storage layer 142 is patterned to expose a top surface of the horizontal semiconductor layer 120. To pattern the data storage layer 142, a temporary spacer (not shown) covering an inner wall of the data storage layer 142 may be formed in the opening 140. The temporary spacer may reduce etching damage to the data storage layer 142 in a patterning process of etching the data storage layer 142. According to an embodiment, the temporary spacer may be formed using a material that can be removed while minimizing or reducing etching damage to the data storage layer 142. For example, in the case that the data storage layer 142, which is in contact with the temporary spacer, is a silicon oxide layer, the temporary spacer may be formed of a silicon nitride layer. According to another embodiment, the temporary spacer may be formed from the same material as the vertical semiconductor pattern 145. For example, the temporary spacer may be formed from amorphous or polycrystalline silicon. In this case, the temporary spacer may be used as the vertical semiconductor pattern 145 without an additional removal process. Subsequently, the data storage layer 142 may be etched using the temporary spacer as an etching mask. As a result, a top surface of the horizontal semiconductor layer 120 may be exposed at a bottom of the opening 140. After etching the data storage layer 142, the temporary spacer may be removed while minimizing or reducing etching damage to the data storage layer 142.

Next, the vertical semiconductor pattern 145 contacting the horizontal semiconductor layer 120 is formed while covering the data storage layer 142. The vertical semiconductor pattern 145 may be formed using a deposition technology having a superior step difference coating characteristic. At this time, the vertical semiconductor pattern 145 may be deposited to have a thickness equal to or less than half of a width of the opening 140. In this case, the vertical semiconductor pattern 145 fills a portion of the opening 140 and may define a vacant region at the center of the opening 140. That is, the vertical semiconductor pattern 145 may be formed in a hollow cylindrical shape or a shell shape. A thickness (i.e., a thickness of the shell) of the vertical semiconductor pattern 145 may be smaller than a width of a depletion region to be formed therein or may be less than an average length of silicon grains constituting polycrystalline silicon. The vacant region defined by the vertical semiconductor pattern 145 may be filled with a buried insulating layer 147. According to another embodiment, the vertical semiconductor pattern 145 may completely fill the opening 140 using a deposition process. In this case, after depositing the vertical semiconductor layer, a planarization process may be performed on the vertical semiconductor pattern 145.

According to another embodiment, the vertical semiconductor pattern 145 may be formed to be single crystalline silicon by performing a phase change process on amorphous silicon or polycrystalline silicon through a thermal process, such as a laser annealing, after depositing amorphous silicon or polycrystalline silicon. According to still another embodiment, the vertical semiconductor pattern 145 may be a single crystalline semiconductor formed through an epitaxial growth process using the horizontal semiconductor layer 120 as a seed.

The vertical semiconductor pattern 145 may include, for example, silicon (Si), germanium (Ge) or combinations thereof. The vertical semiconductor pattern 145 may be formed to have the same conductivity type as the horizontal semiconductor layer 120, which is in contact with the vertical semiconductor pattern 145. Also, the horizontal semiconductor layer 120 may have a crystal structure, such as a single crystalline structure, an amorphous structure, and a polycrystalline structure. Also, according to an embodiment, a discontinuous interface of a crystal structure may be formed between the horizontal semiconductor layer 120 and the vertical semiconductor pattern 145.

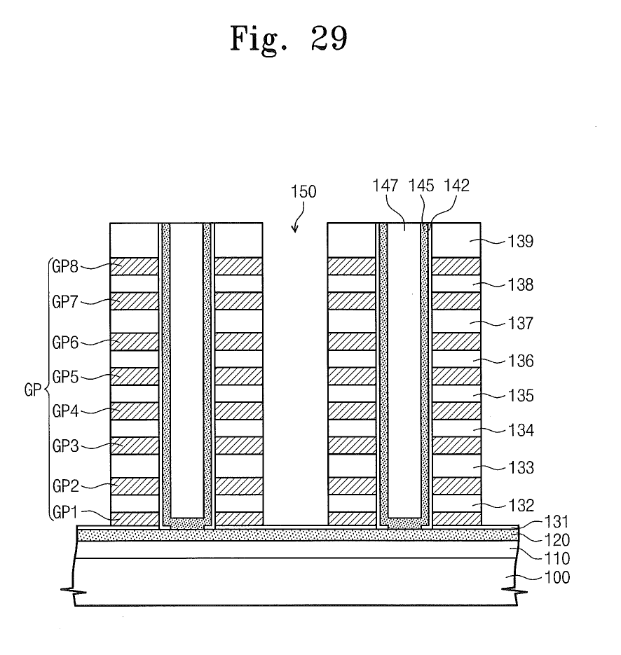

Referring to FIG. 29, as described with reference to FIGS. 19A and 19B, an upper trench 150 exposing the horizontal semiconductor layer 120 is formed between the adjacent vertical semiconductor patterns 145.

The upper trench 150 may be formed to expose sidewalls of the gate conductive layers GP1-GP8 and the insulating layers 132-139 while being spaced apart from the vertical semiconductor patterns 145. In a horizontal view, the upper trenches 150 may be formed in a line shape parallel to each other or in a rectangle. In a vertical depth, the upper trench 150 may be formed to expose the buffer dielectric layer 131 on the horizontal semiconductor layer 120. Alternatively, the upper trenches 150 may be formed to expose a top surface of the horizontal semiconductor layer 120. During a formation of the upper trenches 150, a top surface of the horizontal semiconductor layer 120 exposed by the upper trench 150 may be recessed to have a predetermined depth by an over etching. The upper trench 150 may anisotropically etched to have a different width according to a distance from the substrate 100.

As the upper trench 150 is formed, as illustrated in FIG. 13, the thin layer structure comprised of the gate conductive layers GP1-GP8 and the insulating layers 132-139 may have a line shape parallel to each other. A plurality of vertical semiconductor patterns 145 may penetrate one thin layer structure of a line shape. According to the present embodiment, as the upper trenches 150 are formed, a gate structure GP comprising the gate electrodes GP1-GP8 having a line shape are stacked and may be formed on the horizontal semiconductor layer 120 and a plurality of vertical semiconductor patterns 145 penetrate one gate structure GP to be connected to the horizontal semiconductor layer 120.

After forming a plurality of gate structures GP on the horizontal semiconductor layer 120, as described with reference to FIGS. 23A through 25A, a common source conductive line 170 is formed between the substrate 100 and the horizontal semiconductor layer 120. Forming the common source conductive line 170 may include forming a lower trench 155 by patterning the horizontal semiconductor layer 120 and the lower sacrificial layer 110 and replacing a portion of the lower sacrificial layer 110 with a metal material layer.

More specifically, before forming the lower trench 155, as illustrated in FIG. 3, a spacer 160 covering a sidewall of the gate structure GP is formed on the buffer dielectric layer 131 and the horizontal semiconductor layer 120. The spacer 160 may be formed on an outer sidewall of the gate structure GP by conformally forming an insulating layer along a surface of the gate structure GP, and then anisotropically etching the insulating layer. That is, the spacer 160 covers sidewalls of the gate electrodes GP1-GP8 exposed to the upper trench 150. According to an embodiment, the spacer 160 may be formed from a material having an etching selectivity with respect to the gate electrodes GP1-GP8. For example, the spacer 160 may be formed of a material selected from a silicon oxide layer, a silicon nitride layer, a silicon oxynitride layer, and/or silicon carbide.

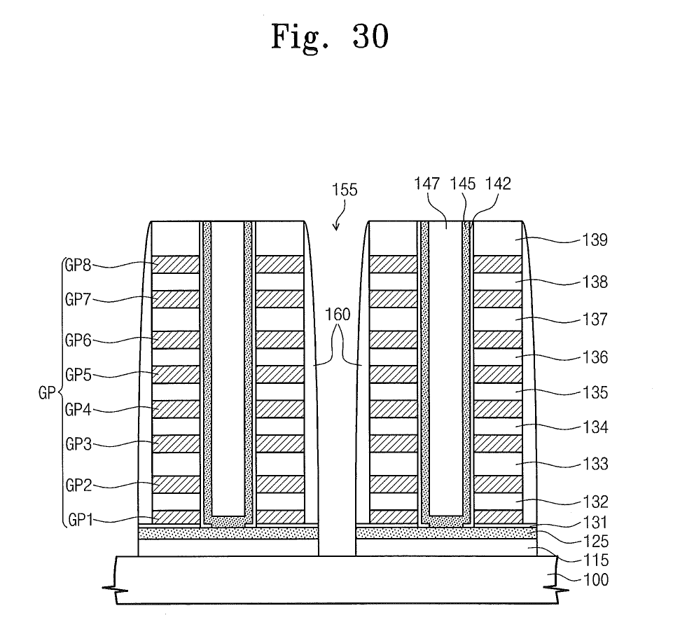

Also, forming the lower trench 155, as illustrated in FIG. 30, includes anisotropically etching the horizontal semiconductor layer 120 and the lower sacrificial layer 110 using the gate structure GP and the spacer 160 as an etching mask. The lower trench 155 can extend from the upper trench 150 between the gate structures GP to expose a top surface of the substrate 100. Also, during formation of the lower trench 155, a top surface of the substrate 100 exposed to the lower trench 155 may be recessed to have a predetermined depth by an over etching. As the lower trench 155 is formed, a horizontal semiconductor pattern 125 and a lower sacrificial layer pattern 115 may be formed under each of the gate structures GP having a line shape by the upper trench 150.

Replacing a portion of the lower sacrificial layer 110 with a metal material layer may include forming a lower recess region by removing a portion of the lower sacrificial layer 110 exposed by the lower trench 155 as described with reference to FIGS. 24A and 24B and forming the common source conductive line in the lower recess region as described with reference to FIGS. 25A and 25B.

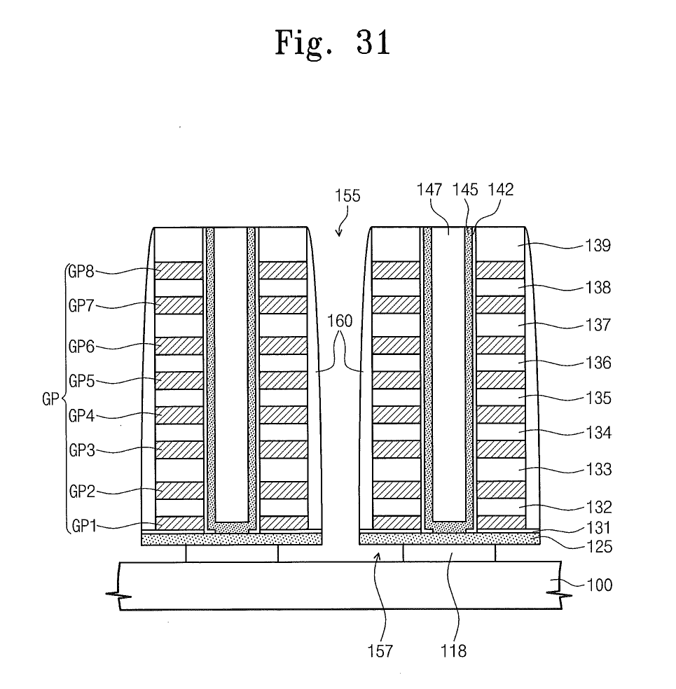

Referring to FIG. 31, forming the lower recess region 157 includes isotropically etching a portion of the lower sacrificial layer 110 by applying an isotropic etching solution to the lower trench 155 so as to expose a sidewall of the lower sacrificial layer 110. For example, in the case that the lower sacrificial layer 110 is a silicon nitride layer, and the insulating layers 132-139 and the spacer 160 are silicon oxide layers, an isotropic etching process may be performed using an etching solution including phosphate acid. As an isotropic etching process is performed, the lower recess region 157 horizontally extending from the lower trench 155 may be formed. Here, a horizontal width of the lower recess region 157 may be determined by the amount of the lower sacrificial layer 110 removed by an isotropic etching process. The lower recess region 157 may expose a portion of bottom surface of the horizontal semiconductor pattern 125 under the gate electrodes GP.

An isotropic etching process may be performed in such a manner that the gate structure GP formed on the lower sacrificial layer 110 does not collapse. That is, as the lower recess region 157 is formed, a portion of bottom surface of the horizontal semiconductor pattern 125 may be exposed and a support pattern 118, which is a remaining portion of the lower sacrificial layer pattern 115, may be formed between the horizontal semiconductor pattern 125 and the substrate 100.

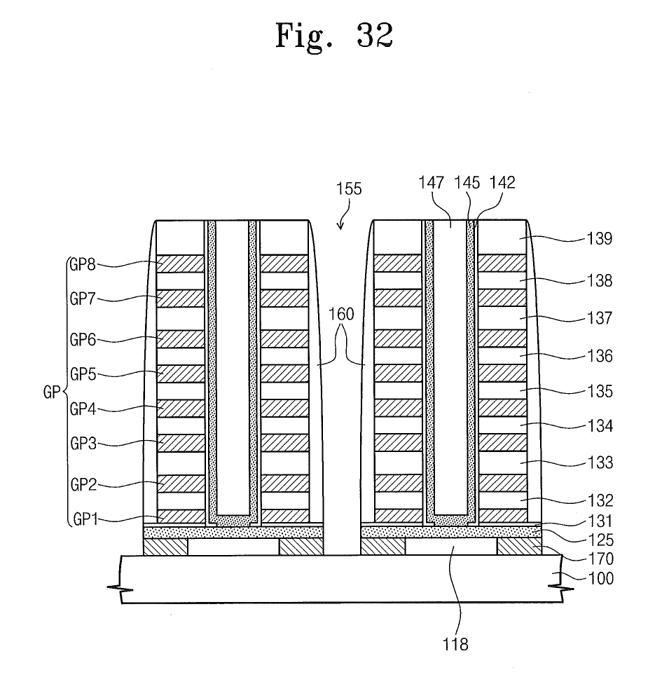

Referring to FIG. 32, the common source conductive line 170 is formed in the lower recess region 157. The common source conductive line 170 formed in the lower recess region 157 may fill a portion or an entire portion of the lower recess region 157.

More specifically, forming the common source conductive line 170, as described with reference to FIGS. 25A and 25B, may include forming a conductive layer filling the lower recess region 157 and the lower trenches 155. Thus, the conductive layer can be directly in contact with a bottom surface of the horizontal semiconductor pattern 125. The conductive material for forming the common source conductive line 170 may be deposited as far as an upper portion of the gate structure GP and may be formed between the gate structures GP by planarizing the conductive layer so that the uppermost insulating layer 139 is exposed. That is, the conductive layer may have a structure extending between the gate structures GP from a lower portion of the gate structure GP. The conductive layer filling a space between the gate structures GP (i.e., the lower and upper trenches 155 and 150) may be separated from the gate electrodes GP1-GP8 by the spacer 160.

The common source conductive line 170 may include at least one material selected from metal (e.g., tungsten, titanium, tantalum, tantalum aluminum, etc.), conductive metal nitrides (e.g., titanium nitride, tantalum nitride, etc.), and metal silicides (e.g., tungsten silicide, cobalt silicide, titanium silicide, nickel silicide, etc.). According to an embodiment, the common source conductive line 170 may be formed by forming conductive metal nitride, which is metal barrier material, and then depositing metal material. As illustrated in FIG. 9, the conductive metal nitride 190a may be directly in contact with a bottom surface of the horizontal semiconductor pattern 125.

After forming the conductive layer in the lower trenches 155, removing the conductive layer may include anisotropically etching the conductive layer using the uppermost insulating layer constituting the thin layer structure and a hard mask pattern (not illustrated) additionally formed on a top surface of the uppermost insulating layer as an etching mask.

According to an embodiment, the conductive layer filling the lower trenches 155 may be removed to locally form the common source line 170 in each of the lower recess regions 157. That is, removing the conductive layer may include exposing a top surface of the substrate 100 by reforming the upper and lower trenches 150 and 155 thereby exposing the spacer 160 between the gate structures GP. According to another embodiment, as illustrated in FIG. 7, the common source conductive line 170 may extend from under any one gate structure GP to under another adjacent gate structure GP. Also, the conductive layer may not be removed between the gate structures GP.

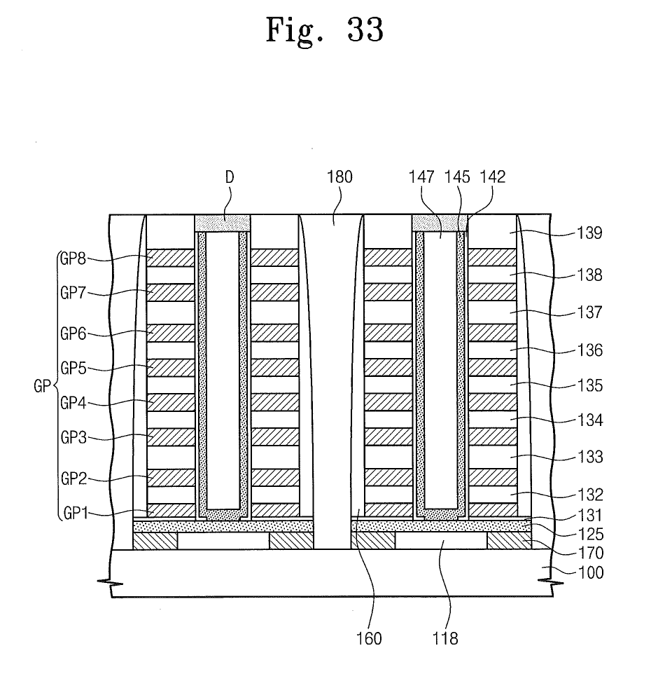

Referring to FIG. 33, a gate separation insulating pattern 180 is formed between the gate structures GP. Forming the gate separation insulating pattern 180 includes filling the upper and lower trenches exposing the spacer 160 with at least one insulating material. According to an embodiment, the gate separation insulating pattern 180 may be at least one of a silicon oxide layer, a silicon nitride layer, and a silicon oxynitride layer. According to an embodiment, the gate separation insulating pattern 180 may be formed from the same material as the spacer 160 on a sidewall of the gate structure GP. Also, according to an embodiment, the gate separation insulating pattern 180 extends between adjacent common source conductive lines 170 and between the gate structures GP to directly contact the substrate 100. According to another embodiment, the gate separation insulating pattern 180 may be formed on a top surface of the common source conductive line 170.

After that, a drain region D may be formed on top surfaces of the gate separation insulating pattern 180 and the vertical semiconductor pattern 145. As illustrated in FIGS. 13 and 14, bit lines 195 electrically connecting the vertical semiconductor patterns 145 may be formed on a top surface of the gate structure GP. The bit lines 195, as illustrated, may be formed along a direction crossing the gate structure GP in a line shape. The bit lines 195 may be connected to the drain region D by a contact plug.

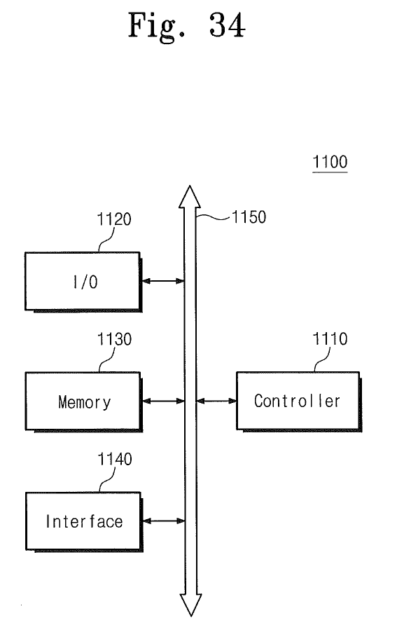

FIG. 34 is a block diagram illustrating an example of a memory system including a semiconductor memory device manufactured according to exemplary embodiments of the inventive concept.

Referring to FIG. 34, a memory system 1100 may be used in a portable computer, a web tablet, a wireless phone, a mobile phone, a digital music player, a memory card and/or all devices that can transmit and/or receive data in a wireless environment.

The memory system 1100 includes a controller 1110, an input/output device 1120, such as a keypad, a keyboard and a display, a memory 1130, an interface 1140 and a bus 1150. The memory 1130 and the interface 1140 communicate with each other through the bus 1150.

The controller 1110 includes at least one microprocessor, at least one digital signal processor, at least one micro controller and/or other processing devices similar to the microprocessor, the digital signal processor, and the micro controller. The memory 1130 may be used to store an instruction executed by the controller 1110. The input/output device 1120 can receive data or a signal from the outside of the system 1100 or transmit data or a signal to the outside of the system 1100. For example, the input/output device 1120 may include a keyboard, a keypad and/or a display device.

The memory 1130 includes a nonvolatile memory device in accordance with exemplary embodiments of the inventive concept. The memory 1130 may further include a different kind of memory, a volatile memory device capable of random access, and various other kinds of memories.

The interface 1140 sends data to a communication network or receives data from a communication network.

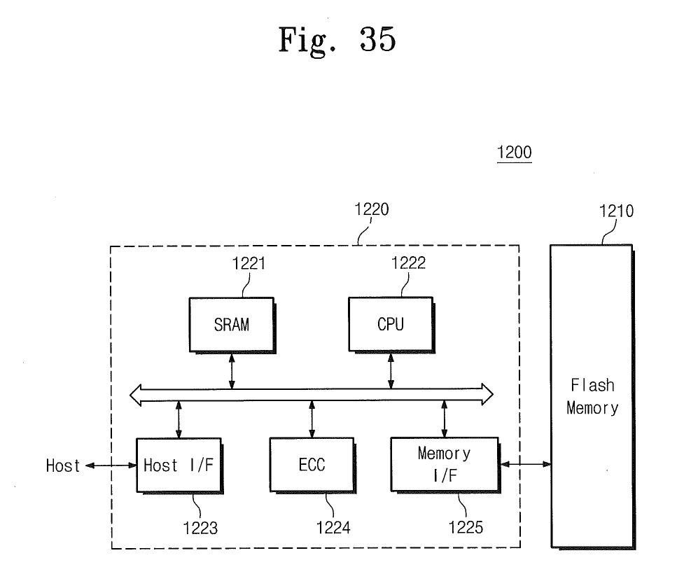

FIG. 35 is a block diagram illustrating an example of a memory card including a semiconductor memory device manufactured according to exemplary embodiments of the inventive concept.

Referring to FIG. 35, the memory card 1200 for supporting a generally large capacity storage capability is fitted with a flash memory device 1210 in accordance with embodiments of the inventive concept. The memory card 1200 in accordance with embodiments of the inventive concept includes a memory controller 1220 controlling all the data exchanges between a host and the flash memory device 1210.

An SRAM 1221 is used as an operation memory of a processing unit 1222. A host interface 1223 includes data exchange protocols of a host connected to the memory card 1200. An error correction block 1224 detects and corrects errors included in data readout from a multi-bit flash memory device 1210. A memory interface 1225 interfaces with the flash memory device 1210 of embodiments of the inventive concept. A processing unit 1222 performs all the control operations for a data exchange of the memory controller 1220. Although not illustrated in the drawing, it is apparent to one of ordinary skill in the art that the memory card 1200 in accordance with the inventive concept can further include a ROM (not shown) storing code data for interfacing with the host.

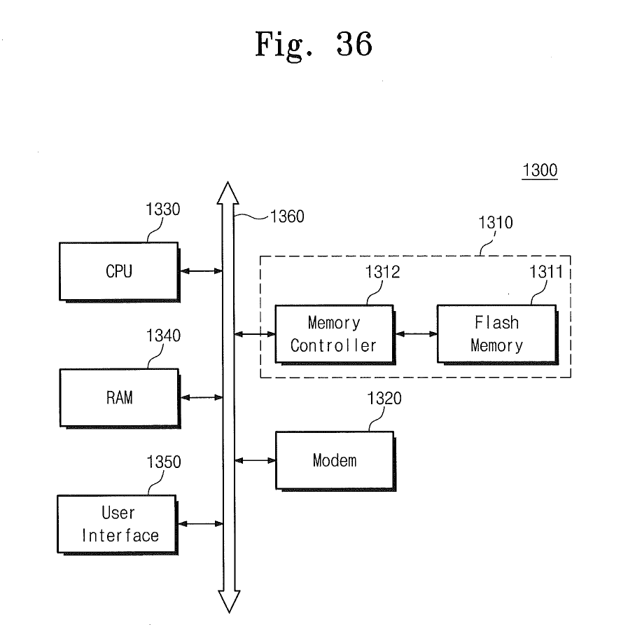

FIG. 36 is a block diagram illustrating an example of an information processing system including a semiconductor memory device manufactured according to exemplary embodiments of the inventive concept.

Referring to FIG. 36, a flash memory system 1310 according to embodiments of the inventive concept is built in a data processing system such as a mobile product or a desktop computer. A data processing system 1300 in accordance with the inventive concept includes the flash memory system 1310 and a modem 1320, a central processing unit (CPU) 1330, a random access memory (RAM) 1340, and a user interface 1350 that are electrically connected to a system bus 1360 respectively. The flash memory system 1310 may be with the same as or substantially similar to the memory system or the flash memory system described above. The flash memory system 1310 stores data processed by the central processing unit 1330 or data received from an external device. Here, the flash memory system 1310 may comprise a solid state disk (SSD) and, in this case, the data processing system 1310 can stably store huge amounts of data in the flash memory system 1310. As reliability increases, the flash memory system 1310 can reduce resources used to correct errors, thereby providing a high speed data exchange function to the data processing system 1300. Although not illustrated in the drawing, it is apparent to one of ordinary skill in the art that the data processing unit 1300 in accordance with embodiments of the inventive concept may further include an application chipset, a camera image processor (CIS) and/or an input/output device.

The flash memory device or the memory device in accordance with embodiments of the inventive concept can be mounted with various types of packages. For example, the flash memory device or the memory device can be mounted by various types of packages such as, but not limited to, PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP) and mounted.

According to an embodiment of the inventive concept, in a three-dimensional NAND flash memory device, a common source conductive line may be formed from a metal material having a low resistivity. As a result, an operation speed of a three-dimensional NAND flash memory device can be improved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

1. A three-dimensional semiconductor memory device, comprising:
a gate structure on a substrate, the gate structure including a plurality of gate electrodes;
conductive lines between the gate structure and the substrate;
a horizontal semiconductor pattern between the gate structure and the conductive lines; and
a vertical semiconductor pattern penetrating the gate structure and connected to the horizontal semiconductor pattern.

2. The three-dimensional semiconductor memory device of claim 1, wherein the conductive line is directly in contact with a bottom surface of the horizontal semiconductor pattern.

3. The three-dimensional semiconductor memory device of claim 1, wherein the conductive line comprises at least a metal material, a conductive metal nitride, and/or a metal silicide.

4. The three-dimensional semiconductor memory device of claim 1, wherein the conductive lines are substantially parallel to the gate electrodes.

5. The three-dimensional semiconductor memory device of claim 1, wherein the horizontal semiconductor pattern has a same conductivity type as the vertical semiconductor pattern at a position adjacent to the vertical semiconductor pattern.

6. The three-dimensional semiconductor memory device of claim 1, wherein the horizontal semiconductor pattern comprises a lower region adjacent to the conductive lines and an upper region adjacent to the gate electrodes,
wherein the upper region has a same conductivity type as the vertical semiconductor pattern and the lower region has an opposite conductivity type to the upper region.

7. The three-dimensional semiconductor memory device of claim 1, wherein the vertical semiconductor pattern has a hollow cylindrical shape and a thickness of the vertical semiconductor pattern is less than a thickness of the horizontal semiconductor pattern.

8. The three-dimensional semiconductor memory device of claim 1, wherein a thickness of the horizontal semiconductor pattern and a thickness of an inversion layer formed in the horizontal semiconductor pattern by a predetermined voltage applied to a lowermost of the gate electrodes adjacent to the substrate are substantially equal.

9. The three-dimensional semiconductor memory device of claim 1, wherein the vertical semiconductor pattern penetrates the horizontal semiconductor pattern to directly contact the conductive lines.

10. The three-dimensional semiconductor memory device of claim 1, further comprising insulating layers between the gate electrodes and a support pattern disposed between the conductive lines under the horizontal semiconductor pattern, wherein the support pattern comprises an insulating material having an etching selectivity with respect to the insulating layers.

11. The three-dimensional semiconductor memory device of claim 1, wherein the gate structure further comprises a data storage layer disposed between the gate electrodes and the vertical semiconductor pattern.

12. The three-dimensional semiconductor memory device of claim 11, wherein the data storage layer extends on top and bottom surfaces of each of the gate electrodes.

13. The three-dimensional semiconductor memory device of claim 1, further comprising an insulating spacer covering a sidewall of the gate structure, wherein the horizontal semiconductor pattern extends under the insulating spacer.

14. The three-dimensional semiconductor memory device of claim 1, wherein the horizontal semiconductor pattern is a first horizontal semiconductor pattern and is separated from a second horizontal semiconductor pattern under another gate structure adjacent to the gate structure.

15. The three-dimensional semiconductor memory device of claim 1, wherein the substrate comprises an insulating material, a semiconductor material, and/or a semiconductor covered with an insulating material.

16-20. (canceled)

21. A three-dimensional semiconductor memory device, comprising:
first and second gate structures on a substrate, each of the first and second gate structures comprising a plurality of gate electrodes;
first and second horizontal semiconductor patterns disposed between the first and second gate structures and the substrate, respectively; and
a vertical semiconductor pattern disposed between the first and second gate structures on the substrate.

22. The three-dimensional semiconductor memory device of claim 21, further comprising:
first and second conductive lines disposed between the first and second horizontal semiconductor patterns and the substrate, respectively.

23. The three-dimensional semiconductor memory device of claim 22, wherein the vertical semiconductor pattern directly contacts the first and second horizontal patterns without directly contacting the first and second conductive lines.

24. The three-dimensional semiconductor memory device of claim 22, wherein the vertical semiconductor pattern directly contacts the first and second horizontal patterns and the first and second conductive lines.

25. The three-dimensional semiconductor memory device of claim 21, further comprising a support pattern disposed between the vertical semiconductor pattern and the substrate.
